(19) United States
(12) Patent Application Publication
(10) Pub. No.: US 2025/0071969 A1
(43) Pub. Date: Feb. 27, 2025

(54) SEMICONDUCTOR DEVICE

(71) Applicant: SAMSUNG ELECTRONICS CO., LTD., Suwon-si (KR)

(72) Inventors: Yun Choi, Suwon-si (KR); Seungmuk Kim, Suwon-si (KR); Inwoo Kim, Suwon-si (KR); Sohyun Park, Suwon-si (KR); Hanseong Shin, Suwon-si (KR); Kiseok Lee, Suwon-si (KR); Hyunjin Lee, Suwon-si (KR); Hosang Lee, Suwon-si (KR); Hongjun Lee, Suwon-si (KR); Heejae Chae, Suwon-si (KR)

(21) Appl. No.: 18/623,816

(22) Filed: Apr. 1, 2024

(30) Foreign Application Priority Data
Aug. 24, 2023 (KR) 10-2023-0111500

(51) Int. Cl. H10B 12/00; H01L 21/027; H01L 21/311

(52) U.S. Cl. CPC H10B 12/315; H01L 21/0273; H01L 21/31144; H10B 12/0335; H10B 12/482

(57) ABSTRACT

A semiconductor device may include a plurality of active patterns disposed on a substrate, a gate structure extending in a first direction, a bit line structure extending in a second direction, and a plurality of capacitors electrically connected to the plurality of active patterns, respectively, the plurality of active patterns having a shape extending in a third direction oblique to the first and second directions, the gate structure passing through centers of the plurality of active patterns, the bit line structure connected to first end portions of the plurality of active patterns, the plurality of capacitors connected to second end portions of the plurality of active patterns, respectively, the first end portion and the second end portion positioned at opposite sides with respect to the gate structure, and the first end portion and the second end portion having point-symmetrical shapes with respect to a center of the active pattern.

### CROSS-REFERENCE TO RELATED APPLICATION

This application claims priority to and the benefit of Korean Patent Application No. 10-2023-0111500 filed in the Korean Intellectual Property Office on Aug. 24, 2023, the entire contents of which is incorporated herein by reference.

### BACKGROUND

### 1. Field

The present disclosure relates to a semiconductor device.

### 2. Description of the Related Art

As semiconductor devices become more highly integrated, the width of active patterns decreases and the spacing between active patterns decreases. Accordingly, active patterns with fine widths and spacings and a method of forming the same are in demand.

For example, multi-patterning technology may be applied to form active patterns with fine width and spacing. Multi-patterning technology is a method of patterning multiple times, e.g., exposure and etching may be repeated two or more times.

### SUMMARY

The present disclosure relates to increasing a contact area of an active pattern of a semiconductor device with a bit line or a capacitor.

In general, aspects of the subject matter described in this specification can be embodied in a semiconductor device including: a plurality of active patterns disposed on a substrate, a gate structure extending in a first direction parallel to an upper surface of the substrate, a bit line structure extending in a second direction parallel to the upper surface of the substrate and crossing the first direction, and a plurality of capacitors electrically connected to the plurality of active patterns, respectively, where the plurality of active patterns have a shape extending in a third direction oblique to the first direction and the second direction, where the gate structure passes through centers of the plurality of active patterns, where the bit line structure is connected to first end portions of the plurality of active patterns, where the plurality of capacitors are connected to second end portions of the plurality of active patterns, respectively, where the first end portion and the second end portion are positioned at opposite sides with respect to the gate structure, and where the first end portion and the second end portion have point-symmetrical shapes with respect to a center of the active pattern.

Another general aspect can be embodied in a semiconductor device including: a plurality of active patterns disposed on a substrate, a gate structure extending in a first direction parallel to an upper surface of the substrate, a bit line structure extending in a second direction parallel to the upper surface of the substrate and crossing the first direction, and a plurality of capacitors electrically connected to the plurality of active patterns, respectively, where the plurality of active patterns have a shape extending in a third direction oblique to the first direction and the second direction, where the gate structure passes through centers of the plurality of active patterns, where the bit line structure is connected to first end portions of the plurality of active patterns, where the plurality of capacitors are connected to second end portions of the plurality of active patterns, respectively, where the first end portion and the second end portion are positioned at opposite sides with respect to the gate structure, and where a width along the second direction of the first end portion and the second end portion is greater than a width along the second direction of intermediate portion between the first end portion and the second end portion.

Another general aspect can be embodied in a semiconductor device including: a plurality of active patterns disposed on a substrate, a gate structure extending in a first direction parallel to an upper surface of the substrate, a bit line structure extending in a second direction parallel to the upper surface of the substrate and crossing the first direction, and a plurality of capacitors electrically connected to the plurality of active patterns, respectively, where the plurality of active patterns have a shape extending in a third direction oblique to the first direction and the second direction, where each active pattern may include, in a plan view, a central portion through which the gate structure passes, a first end portion connected to the bit line structure, and a second end portion connected to the capacitor, where the first end portion and the second end portion are positioned at opposite sides of the gate structure, where the first end portion and the second end portion have a point-symmetrical shape with respect to a center of each active pattern, and where central portions of the plurality of active patterns are arranged side by side in the first direction, first end portions of the plurality of active patterns are arranged side by side in the second direction, and second end portions of the plurality of active patterns are arranged side by side in the second direction.

In some implementations, a contact area of an active pattern of a semiconductor device with a bit line or a capacitor may be increased.

### BRIEF DESCRIPTION OF THE DRAWINGS

FIG. 1 is a top plan view schematically showing an example of a semiconductor device.

FIG. 2 is a top plan view of an example of a semiconductor device.

FIG. 3 and FIG. 4 are cross-sectional views of an example of a semiconductor device.

FIG. 5A to FIG. 5I are plan views of examples of active patterns.

FIG. 6A to FIG. 20 are plan views and cross-sectional views showing an example of a process for patterning an active pattern.

FIG. 21A to FIG. 25 are plan views and cross-sectional views showing an example of a process for patterning an active pattern.

FIG. 26A to FIG. 39 are plan views and cross-sectional views showing an example of a process for patterning an active pattern.

FIG. 40A to FIG. 50 are plan views and cross-sectional views showing an example of a process for patterning an active pattern.

FIG. 51A to FIG. 70 are plan views and cross-sectional views showing an example of a process for patterning an active pattern.

FIG. 71A to FIG. 82 are plan views and cross-sectional views showing an example of a process for patterning an active pattern.

### DETAILED DESCRIPTION

The present disclosure will be described more fully hereinafter with reference to the accompanying drawings, in which examples of the disclosure are shown. As those skilled in the art would realize, the described examples may be modified in various different ways, all without departing from the spirit or scope of the present disclosure.

In order to clearly describe the subject matter of the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for case of description, the thicknesses of some layers and areas are exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

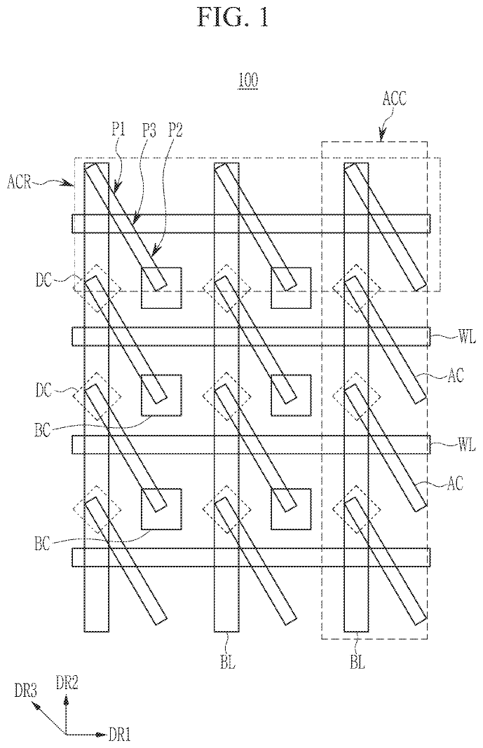

FIG. 1 is a top plan view schematically showing an example of a semiconductor device 100.

The semiconductor device 100 includes a plurality of active patterns AC. In some implementations, one memory cell may be disposed within each active pattern. One transistor and one capacitor may be included in one active pattern.

Referring to FIG. 1, the plurality of active patterns AC are disposed on substrate in a first direction DR1 and a second direction DR2. The first direction DR1 and the second direction DR2 may be parallel to an upper surface of the substrate. The plurality of active patterns AC may have a shape extending in a third direction DR3 oblique to the first direction DR1 and the second direction DR2. Active pattern AC may include a central portion P3 through which a word line WL extending along the first direction DR1 passes. Active pattern AC may include a first end portion P1 and a second end portion P2 positioned at both sides with respect to the central portion P3.

The first end portion P1 may be connected to a bit line BL extending along the second direction DR2. The second direction DR2 may cross the first direction DR1. The second direction DR2 may be, for example, perpendicular to the first direction DR1. The second end portion P2 may be connected to a capacitor.

The central portions P3 of the plurality of active patterns AC may be arranged along the first direction DR1. Each of the first end portions P1 of the plurality of active patterns AC may be arranged along the second direction DR2. The first end portions P1 of the plurality of active patterns AC may be arranged side by side with the third direction DR3. Each of the second end portions P2 of the plurality of active patterns AC may be arranged along the second direction DR2.

The plurality of active patterns AC may form an active row ACR disposed side by side in the first direction DR1. The plurality of active patterns AC may form an active column ACC disposed side by side in the second direction DR2. For example, at least a portion of neighboring active rows ACR may be disposed between neighboring active patterns AC in the active row ACR.

The semiconductor device 100 may further include a gate structure extending in the first direction DR1. The gate structure may include the word line WL. The gate structure may be disposed to pass through centers of active patterns AC included in the active row ACR. The first end portion P1 and the second end portion P2 may be positioned at both sides with respect to the gate structure both sides. In the present disclosure, the first end portion P1 and the second end portion P2 are not limited to portions farthest from the central portion P3 in a length direction of the active pattern AC, but the first end portion P1 may include a portion positioned at a first side of the second direction DR2 with respect to the gate structure, and the second end portion P2 may include a portion positioned at a second side of the second direction DR2 with respect to the gate structure.

The semiconductor device 100 may further include a bit line structure extending in the second direction DR2, in a plan view. The bit line structure may include the bit line BL. The bit line structure may be electrically connected to the first end portion P1 of the active patterns AC included in the active column ACC. The first end portion P1 of the active pattern AC may be directly connected to the bit line structure. For example, a contact plug may not be positioned between the first end portion P1 and the bit line structure. The first end portion P1 may contact the bit line structure. In FIG. 1, a portion contacting the bit line structure of the first end portion P1 may be indicated as a direct contact DC.

The semiconductor device 100 may further include a plurality of capacitors electrically connected to the plurality of active patterns AC, respectively. The plurality of capacitors may be electrically connected to the second end portion P2 of the active patterns AC, respectively. The second end portion P2 of the active pattern AC may be connected to the capacitor through a contact plug. For example, at least one of the contact plug or the landing pad may be positioned between the second end portion P2 and capacitor. In FIG. 1, a portion contacting the landing pad or contact plug of the second end portion P2 may be indicated as a buried contact BC.

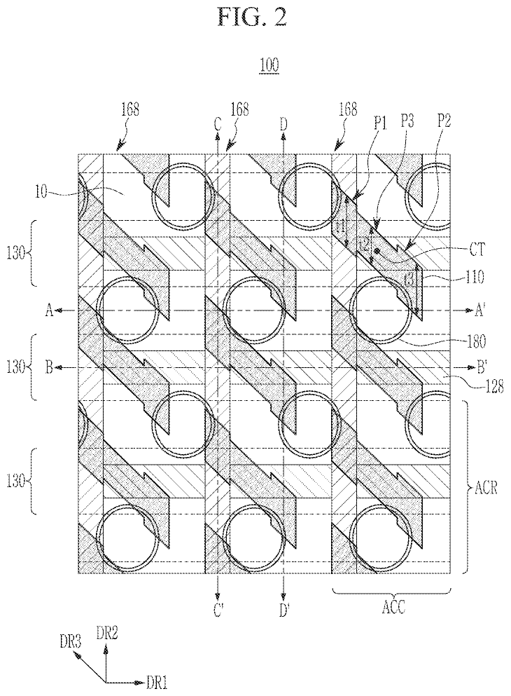

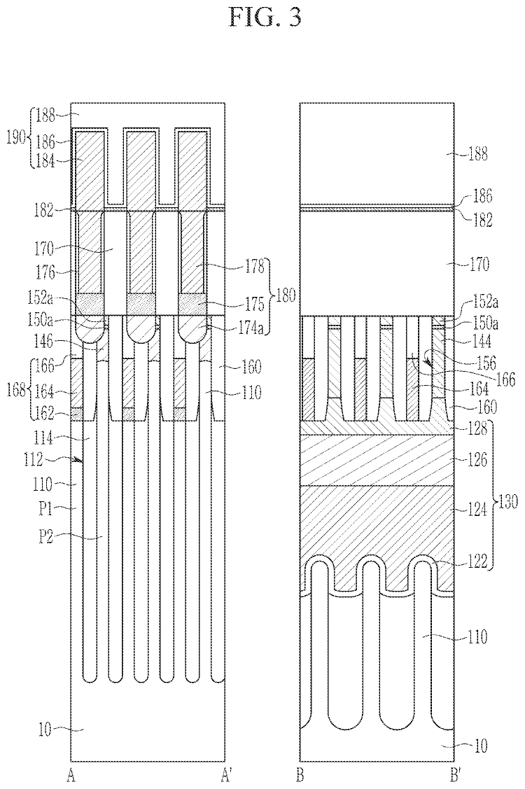

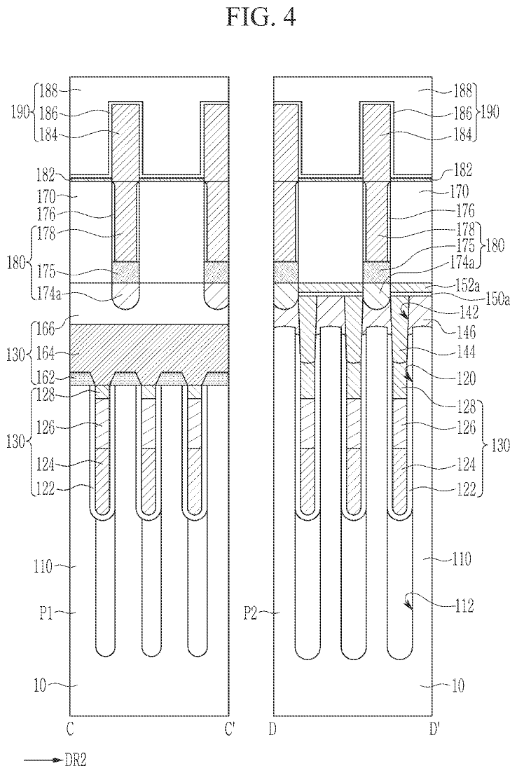

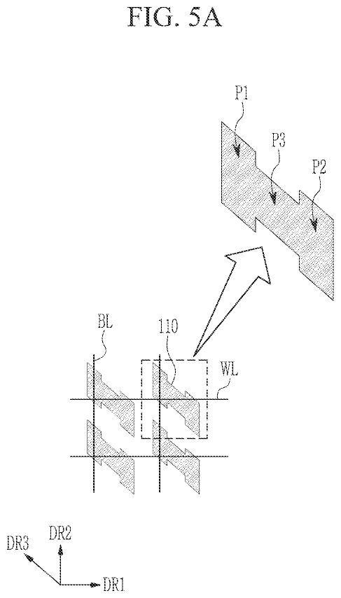

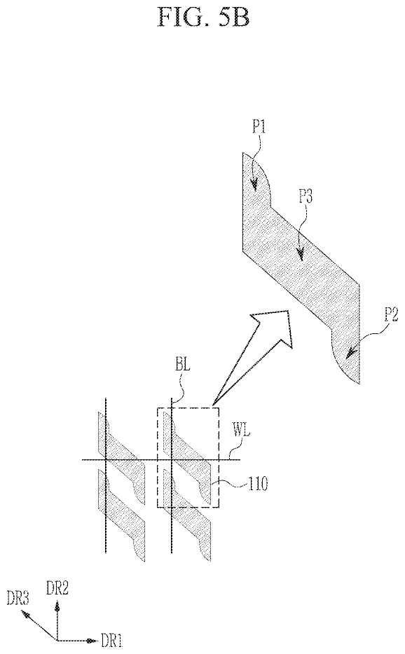

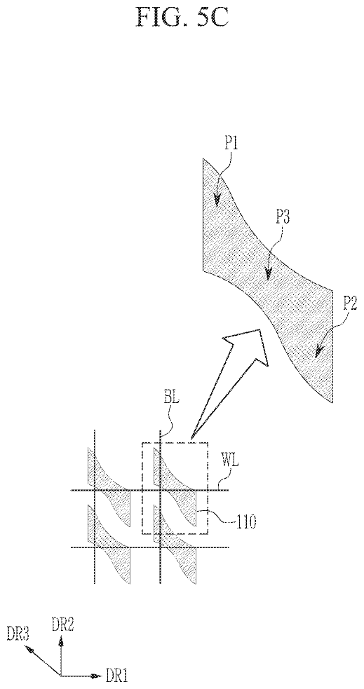

FIG. 2 is a top plan view of the semiconductor device 100. FIG. 3 and FIG. 4 are cross-sectional views of the semiconductor device 100.

For convenience, FIG. 2 illustrates only some of components of the semiconductor device 100. FIG. 3 shows cross-sections along lines A-A′ and B-B′ of FIG. 2. FIG. 4 shows cross-sections along lines C-C′ and D-D′ of FIG. 2.

Referring to FIG. 2 to FIG. 4, a substrate 10 includes a device isolation pattern 114 and active patterns 110 on its upper portion. The device isolation pattern 114 may be disposed within a device isolation trench 112. The active patterns 110 may be defined by the device isolation pattern 114.

The substrate 10 may include, for example, a semiconductor material such as silicon, germanium, or silicon-germanium, or a group III-V compound such as GaP, GaAs, and GaSb. For example, the substrate 10 may be a silicon-on-insulator (SOI) substrate or a germanium-on-insulator (GOI) substrate.

The device isolation pattern 114 may include an insulating material. For example, the device isolation pattern 114 may include silicon oxide. The active pattern 110 may include the same material as the substrate 10.

In some implementations, the active pattern 110 may have a shape extending in the third direction DR3. For example, the active pattern 110 may have the third direction DR3 as its length direction. The third direction DR3 may be a direction oblique to the first direction DR1 and the second direction DR2. For example, the first direction DR1 and the second direction DR2 may be parallel to the substrate 10, and the second direction DR2 may cross the first direction DR1. For example, the second direction DR2 may be perpendicular to the first direction DR1. For example, the third direction DR3 may be inclined from the first direction DR1 at an angle of 35 degrees or more and 50 degrees or less, but is not limited thereto.

In some implementations, a gate structure 130 may pass through a center CT of the active pattern 110. The active pattern 110 may include the first end portion P1 and the second end portion P2 positioned at both sides with respect to the gate structure 130 extending in the first direction DR1.

In some implementations, the first end portion P1 may be electrically connected to a bit line structure 168 extending in the second direction DR2. For example, the first end portion P1 may be directly connected to the bit line structure 168. In some implementations, the second end portion P2 may be electrically connected to a capacitor 190. For example, the second end portion P2 may be connected to the capacitor 190 through a contact structure 180.

In some implementations, the first end portion P1 and the second end portion P2 may have a point-symmetrical shape with respect to the center CT of the active pattern 110. For example, the planar shape of the first end portion P1 and the second end portion P2 may be quadrangular, but is not limited thereto. As another example, the planar shape of the first end portion P1 and the second end portion P2 may be in a circular shape with a portion cut off.

In some implementations, a width t1 along the second direction DR2 of the first end portion P1 and a width t3 along the second direction DR2 of the second end portion P2 may be greater than a width t2 along the second direction DR2 of an intermediate portion between the first end portion P1 and the second end portion P2. For example, areas of the first end portion P1 and the second end portion P2 may be wider than in the case where the width t1 along the second direction DR2 of the first end portion P1, the width t3 along the second direction DR2 of the second end portion P2, and the width t2 along the second direction DR2 of the intermediate portion are the same. That is, an area of the direct contact DC through which the active pattern 110 is connected to the bit line structure 168, and an area of the buried contact BC through which the active pattern 110 is connected to the capacitor 190 may be relatively wide, e.g., compared to an active pattern 110 with a parallelogram shape and same area.

In some implementations, a planar shape of a side surface of the first end portion P1 and the second end portion P2 extending along the third direction DR3 and a planar shape of a side surface of the intermediate portion extending along the third direction DR3 may be a straight line, but the planar shape is not limited thereto. For example, the planar shape of a side surface of the first end portion P1 and the second end portion P2 extending along the third direction DR3 and the planar shape of a side surface of the intermediate portion extending along the third direction DR3 may be a one connected curved line. As another example, the planar shape of a side surface of the intermediate portion extending along the third direction DR3 may be a straight line, and the planar shape of a side surface of the first end portion P1 and the second end portion P2 extending along the third direction DR3 may be a curved line.

In some implementations, the side surface extending along the third direction DR3 connecting the first end portion P1 or the second end portion P2 and the intermediate portion may be in a stepped shape. For example, a side surface of the first end portion P1 or the second end portion P2 extending in the third direction DR3 and a side surface of the intermediate portion extending in the third direction DR3 may be connected by a line extending in the second direction DR2.

In some implementations, the active pattern 110 has a shape such that a center line, e.g., a line that passes through the center CT of the active pattern 110 and is parallel to the third direction DR3, marks the locations where the distance between the center line and edge of the active pattern 110 along the second direction DR2 are the same on each side of the active pattern, e.g., upper and lower sides.

In some implementations, central portions of a plurality of active patterns 110 may be arranged along the first direction DR1. The first end portions P1 of the plurality of active patterns 110 may be arranged along the second direction DR2. The first end portions P1 of the plurality of active patterns 110 may be arranged side by side along the third direction DR3. The second end portions P2 of the plurality of active patterns 110 may be arranged along the second direction DR2. In other words, the active patterns 110 can be arranged in a lattice form, such as in FIG. 2. In each direction, the active patterns 110 are spaced by spaced by a constant amount, e.g., a first distance in the first direction DR1, a second distance in the second direction DR2, and a third distance in the third direction DR3.

In some implementations, the active patterns 110 disposed parallel in the first direction DR1 may be referred to as the active row ACR. The active patterns 110 arranged along the second direction DR2 may be referred to as the active column ACC. The first end portion P1 and the second end portion P2 of the active patterns 110 disposed in the same active column ACC may overlap in the second direction DR2. Central portions of the active patterns 110 disposed in the same active row ACR may be parallel in the first direction DR1.

In some implementations, a first end portion P1 of a first active pattern is adjacent to a second end portion P2 of a second, neighboring active pattern 110 in the same active row ACR. For example, along the first direction DR1, the second end portion P2 in a first active row ACR is between first end portions P1 of two adjacent active patterns 110 in a neighboring second active row ACR. Similarly, along the first direction DR1, the first end portion P1 in a first active row ACR is between second end portions P2 of two adjacent active patterns 110 in another neighboring second active row ACR. In some implementations, the first portion P1 of an active pattern 110 in a first active row ACR overlaps the second portion P2 of an active pattern 110 in a second active row ACR neighboring the first active row ACR.

In some implementations, the gate structures 130 may be spaced apart in the second direction DR2. The second end portion P2 of the active patterns 110 disposed in the same active row ACR may be connected to the same gate structure 130. In some implementations, the bit line structures 168 may be spaced apart in the first direction DR1. The first end portions P1 of the active patterns 110 disposed in the same active column ACC may be connected to the same bit line structure 168.

In some implementations, contact structures 180 may be repeatedly arranged, in a plan view, as a honeycomb structure disposed at a center and each vertex of hexagon. For example, the contact structure 180 may be positioned between neighboring active patterns 110 in an active column ACC or in an active row ACR, e.g., partially overlapping the first end portion P1 of a first active pattern 110 and the second end portion P2 of a second active pattern 110. For example, the contact structure 180 may be positioned between the first end portion P1 of a first active pattern 110 and the second end portion P2 of another active pattern 110 in a neighboring row ACR disposed at a different location along the first direction DR1, e.g., the active patterns 110 neighboring in the third direction DR3, and may partially overlap the first end portion P1 and the second end portion P2. The first end portion P1 of the active pattern 110 and the contact structure 180 may be insulated. The second end portion P2 of the active pattern 110 and the contact structure 180 may be electrically connected.

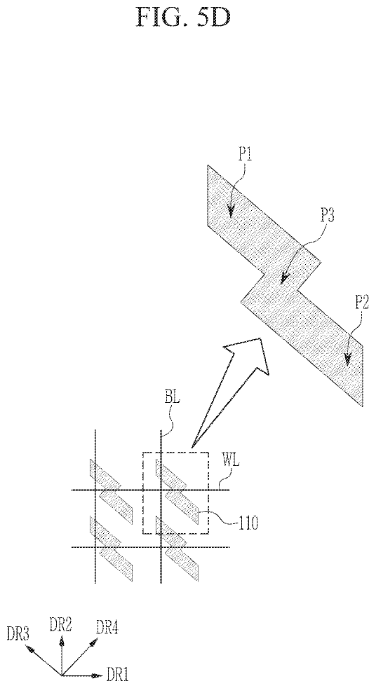

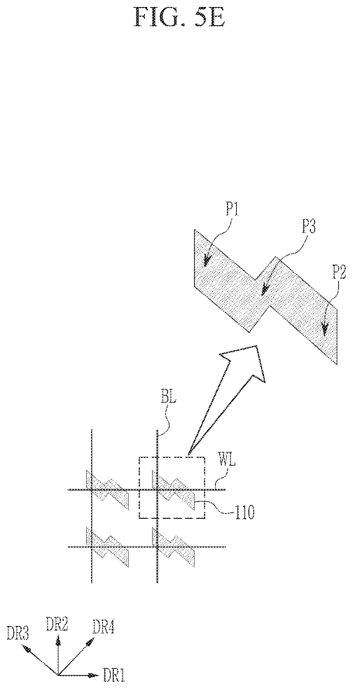

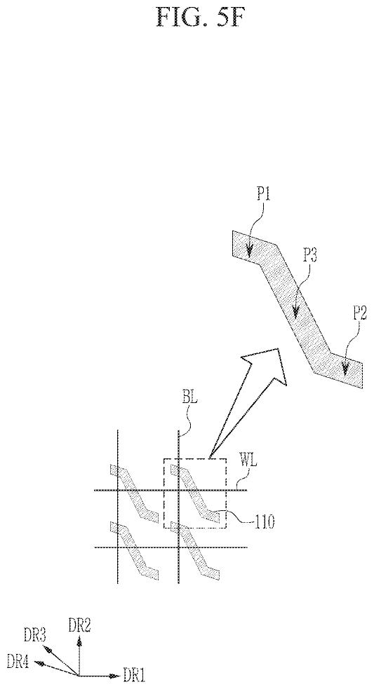

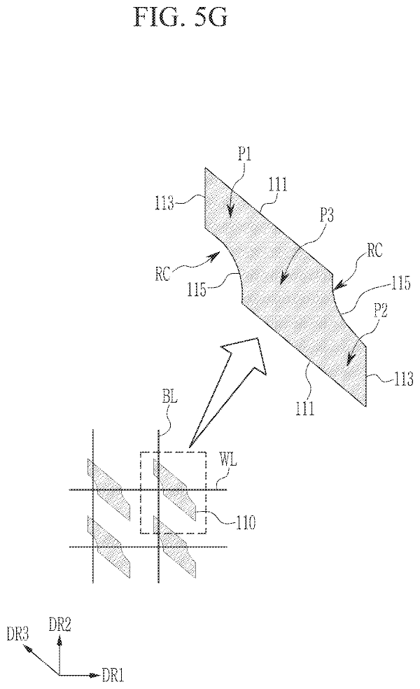

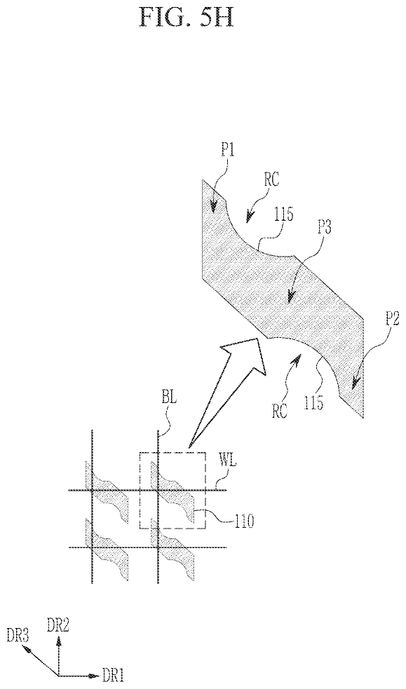

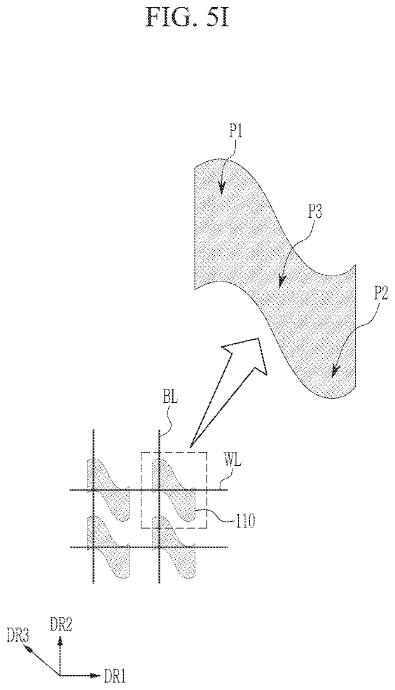

The active patterns 110 may have a shape different from the above-described shape while having the above-described arrangement. Various examples of shapes of the active pattern 110 will be described later with reference to FIG. 5A to FIG. 5I.

A first recess 120 extending in the first direction DR1 may be provided in an upper portion of the active pattern 110 and the device isolation pattern 114. The gate structure 130 may be provided inside the first recess 120. The gate structure 130 may extend to penetrate the upper portion of the active pattern 110 and device isolation pattern. The gate structure 130 may be provided as a word line.

One gate structure 130 may be disposed to one active pattern 110. The gate structure 130 may pass through centers CT of the plurality of active patterns 110 disposed in the same active row ACR, and extend in the first direction DR1. In some implementations, the active pattern 110 may include a central portion through which the gate structure 130 passes, and the first end portion P1 and the second end portion P2 are positioned at both sides of the gate structure 130. In a plan view, the first end portion P1 may be disposed above the gate structure 130, and the second end portion P2 may be disposed below the gate structure 130. In the active pattern 110, a portion adjacent to an outer side of a first sidewall of the first recesses 120 may be the first end portion P1, and a portion adjacent to an outer side of a second sidewall of the first recesses 120 may be the second end portion P2. The second sidewall may face the first sidewall.

A first impurity region may be formed in the first end portion P1 of the active pattern 110, and a second impurity region may be formed in the second end portion P2. The gate structure 130, the first impurity region, and the second impurity region may be provided as a cell transistor. The first impurity region and the second impurity region may be doped with, for example, n-type impurities.

The gate structures 130 may be regularly arranged. The gate structures 130 may be spaced apart in an equal interval in the second direction DR2.

In some implementations, the gate structure 130 may include a gate insulation pattern 122, a first gate pattern 124, a second gate pattern 126, and a gate mask 128. The gate insulation pattern 122 may include, for example, an oxide such as silicon oxide. The first gate pattern 124 may include a metal material such as tungsten. The second gate pattern 126 may include, for example, polysilicon. The gate mask 128 may include, for example, a nitride such as silicon nitride.

In some implementations, the gate insulation pattern 122 may be formed on an upper surface and a sidewall of the active pattern 110 positioned in a lower portion of the first recess 120. Accordingly, the gate structure 130 may act as a gate of a fin field effect transistor (FinFET).

In some implementations, a height of an upper surface of the first end portion P1 of the active pattern 110 may be lower than a height of an upper surface of the second end portion P2 of the active pattern 110.

In some implementations, first contact plugs 146 in an isolated shape may be provided by contacting the upper surface of the second end portion P2 of the active patterns 110. First insulation patterns 144 may be provided between the first contact plugs 146 in the second direction DR2. The first insulation patterns 144 may contact an upper surface of the gate mask 128 of the gate structure 130. The first contact plug 146 may include, for example, polysilicon doped with impurities. The first insulation pattern 144 may include, for example, silicon nitride.

The first contact plug 146 and the first insulation pattern 144 may be disposed alternately and repeatedly in the second direction DR2. The first contact plug 146 and the first insulation pattern 144 may be adjacent in the second direction DR2. The structure in which the first contact plug 146 and the first insulation pattern 144 are alternately disposed may have a sinuous line shape extending lengthwise in the second direction DR2. The structure in which the first contact plug 146 and the first insulation pattern 144 are alternately disposed may be hereinafter referred to as a first line structure.

In some implementations, a first buffer layer pattern 150a and a second buffer layer pattern 152a may be provided on an upper surface of the first line structure. The first buffer layer pattern 150a may include, for example, silicon oxide. The second buffer layer pattern 152a may include, for example, silicon nitride.

In some implementations, a first opening 156 extending in the second direction DR2 may be disposed between the first line structures. The first end portion P1 of the active pattern 110, the device isolation pattern 114, and the gate mask 128 of the gate structure 130 may be exposed on a bottom surface of the first opening 156. On the bottom surface of the first opening 156, the first end portion P1 of the active pattern 110 and the gate mask 128 of the gate structure 130 may be disposed alternately and repeatedly in the second direction DR2. The gate mask 128 on a bottom surface of a first opening 145 may have an etched upper portion, resulting in an upper surface lower than other portions of the gate mask 128.

In some implementations, an insulation spacer 160 may be provided on a sidewall of the first opening 156. The insulation spacer 160 may cover the active pattern 110, the first contact plug 146, the first insulation pattern 144, the first buffer layer pattern 150a, the second buffer layer pattern 152a, and the gate mask 128, which are exposed on the sidewall of the first opening 156. The insulation spacer 160 may extend in the second direction DR2. The first end portion P1 of the active pattern 110 may be exposed on the bottom surface of the first opening 156 between the insulation spacer 160. The insulation spacer 160 may include, for example, silicon oxide.

In some implementations, the bit line structure 168 may be provided inside the first opening 156 between the insulation spacer 160. The bit line structure 168 may contact the first end portion P1 of the active pattern 110, and may extend in the second direction DR2. The insulation spacer 160 may be disposed between the bit line structure 168 and the active pattern 110.

In some implementations, the bit line structure 168 may include a first metal silicide pattern 162, a bit line pattern 164, and a second insulation pattern 166. As illustrated, the first metal silicide pattern 162 may be disposed only on the first end portion P1 of the active pattern 110 exposed by the first opening 156, but not on the gate mask 128 of the gate structure 130 exposed by the first opening 156. In this case, the first metal silicide pattern 162 may be spaced apart from each other in the second direction DR2. That is, the bit line structure 168 may have a structure in which the first metal silicide pattern 162, the bit line pattern 164, and the second insulation pattern 166 are stacked, on the first end portion P1 of the active pattern 110 within the first opening 156, and may have a structure in which the bit line pattern 164 and the second insulation pattern 166 are stacked, on the gate mask 128 within the first opening 156.

As another example, the first metal silicide pattern 162 may be formed over a bottom surface of the first opening 156. That is, the bit line structure 168 may have a structure in which the first metal silicide pattern 162, the bit line pattern 164, and the second insulation pattern 166 are stacked, on the gate mask 128 and the first end portion P1 of the active pattern 110 within the first opening 156.

The first metal silicide pattern 162 may include, for example, a metal silicide such as cobalt silicide, nickel silicide, or titanium silicide. The bit line pattern 164 may include, for example, a metal material such as tungsten, niobium, copper, or aluminum. The second insulation pattern 166 may include, for example, silicon nitride.

In some implementations, upper surfaces of the bit line structure 168, the insulation spacer 160, and the second buffer layer pattern 152a may be positioned on the same plane.

In some implementations, bottom surface of the bit line structure 168 may be lower than the upper surface of the second end portion P2 of the active pattern 110. In a cross-section, a sidewall of the bit line structure 168 may face a sidewall of at least a portion of the second end portion P2s of the active pattern 110.

In some implementations, a first mold layer 170 may be provided to cover upper surfaces of the bit line structure 168, the insulation spacer 160, and the second buffer layer pattern 152a. The first mold layer 170 may include an insulating material having etch selectivity with respect to silicon oxide. The first mold layer 170 may include, for example, silicon nitride, SiOCN, or SiOC.

In some implementations, the contact structure 180 penetrating the first mold layer 170 and contacting the first contact plug 146 may be provided. The contact structure 180 and the first contact plug 146 may be electrically connected to the second end portion P2 of the active pattern 110. The contact structure 180 may contact a portion of an upper surface of the first contact plug 146. In some implementations, a center of the contact structure 180 and a center of the first contact plug 146 may be disposed offset to each other, not being vertically aligned.

In some implementations, the contact structure 180 may contact the first contact plug 146, the insulation spacer 160 neighboring the first contact plug 146, and the second insulation pattern 166 neighboring the insulation spacer 160. A bottom surface of the contact structure 180 may be lower than an uppermost surface of the first contact plug 146. The bottom surface of the contact structure 180 may be lower than an uppermost surface of the bit line structure 168.

In some implementations, the contact structure 180 may include a silicon pattern 174a, a second metal silicide pattern 175, and a second contact plug 178, which are doped with impurities. The second metal silicide pattern 175 may include, for example, a metal silicide such as cobalt silicide, nickel silicide, or titanium silicide. The second contact plug 178 may include, for example, a metal such as tungsten, niobium, copper, or aluminum.

In some implementations, an inner spacer 176 may be provided to surround a sidewall of the second contact plug 178. The inner spacer 176 may include an insulating material. The inner spacer 176 may include, for example, silicon nitride.

In some implementations, second contact plugs 178 may be repeatedly arranged, in a plan view, as a honeycomb structure disposed at a center and each vertex of hexagon.

In some implementations, an etch stop layer 182 may be provided on the second contact plugs 178 and the first mold layer 170. The etch stop layer 182 may include, for example, silicon nitride.

In some implementations, the capacitor 190 may be provided on a second contact plug 189. The capacitor 190 may include a lower electrode 184, a dielectric layer 186, and an upper electrode 188. The lower electrode 184 may penetrate the etch stop layer 182, and contact the second contact plug 178. The lower electrode 184 of the capacitor 190 may be electrically connected to the second end portion P2 of the active pattern 110 through the contact structure 180 and the first contact plug 146.

In some implementations, lower electrodes 184 may be repeatedly arranged, in a plan view, as a honeycomb structure disposed at a center and each vertex of hexagon. The lower electrode 184 may have, for example, a pillar shape or a cylinder shape.

As described above, one gate structure 130 and one capacitor 190 may be disposed within each active pattern 110. The gate structure 130 may pass through a central portion of the active pattern 110 and extend in the first direction DR1. The first end portion P1 and the second end portion P2 of the active pattern 110 may be positioned at both sides with respect to the gate structure 130 both sides. The bit line structure 168 may directly contact the first end portion P1 of the active pattern 110 and extend in the second direction DR2. The first end portion P1 of the active pattern 110 may be electrically connected to the bit line structure 168. The second end portion P2s of the active pattern 110 may be electrically connected to the capacitor 190. The second end portion P2s of the active pattern 110 may be connected to the capacitor 190 through the first contact plug 146 and the contact structure 180.

As the areas of the first end portion P1 and the second end portion P2 becomes wider, the area of the direct contact DC that the active pattern 110 and the bit line structure 168 directly contact and the area of the buried contact BC connecting between the active pattern 110 and the capacitor 190 may increase. An area of the direct contact DC may mean, for example, an area in which the active pattern 110 and the bit line structure 168 vertically overlap. The area of the buried contact BC may mean, for example, an area in which the first contact plug 146 and the contact structure 180 vertically overlap.

FIG. 5A to FIG. 5I are plan views of examples of the active patterns 110.

In FIG. 5A to FIG. 5I, the word line WL may indicate a portion in which the gate structure 130 of FIG. 2 to FIG. 4 is formed, and the bit line BL may indicate a portion in which the bit line structure 168 of FIG. 2 to FIG. 4 is formed. The word line WL may extend in the first direction DR1, and the bit line BL may extend in the second direction DR2. For example, the second direction DR2 may be perpendicular to the first direction DR1.

Hereinafter, the word line WL may pass through the central portion P3 of the active pattern 110. The central portion P3 may mean a portion adjacent to the center of the active pattern 110. In a plan view, the first end portion P1 and the second end portion P2 of the active pattern 110 may be positioned at both sides of the word line WL. In this example, the first end portion P1 of the active pattern 110 is the upper portion, e.g., the portion mostly above the world line WL in a plan view. In this example, the second end portion P2 of the active pattern 110 is the lower portion, e.g., the portion mostly below the word line WL.

In the example of FIG. 5A, the plurality of active patterns 110 may have a shape extending in the third direction DR3 oblique to the first direction DR1 and the second direction DR2. For example, the first end portions P1 of the plurality of active patterns 110 may be spaced apart along the third direction DR3. For example, the third direction DR3 may be inclined at an angle between 35 degrees to 50 degrees with respect to the first direction DR1, but is not limited thereto.

In some implementations, the first end portions P1 of the plurality of active patterns 110 may be arranged along the second direction DR2. The second end portions P2 of the plurality of active patterns 110 may be arranged along the second direction DR2. The central portions P3 of the plurality of active patterns 110 may be arranged along the first direction DR1.

In some implementations, each active pattern 110 may have a shape extending in the third direction DR3. The active pattern 110 may have a length in the third direction DR3. The active pattern 110 may have a width in the second direction DR2.

In some implementations, the first end portion P1 and the second end portion P2 of the active pattern 110 may have a point-symmetrical shape with respect to the center of the active pattern 110. For example, the center of the active pattern 110 may mean a center of a length direction of the active pattern 110. For example, the planar shape of the first end portion P1 and the second end portion P2 may be quadrangular.

In some implementations, a width along the second direction DR2 of the first end portion P1 and the second end portion P2 of the active pattern 110 may be greater than a width along the second direction DR2 of the intermediate portion between the first end portion P1 and the second end portion P2. For example, the intermediate portion may mean a portion connecting the first end portion P1 and the second end portion P2. For example, an interval between both side surfaces of the first end portion P1 extending along the third direction DR3 may be wider than an interval between both side surfaces of the intermediate portion extending along the third direction DR3. In addition, an interval between both side surfaces of the second end portion P2 extending along the third direction DR3 may be wider than the interval between both side surfaces of the intermediate portion extending along the third direction DR3.

In some implementations, the side surface of the first end portion P1 and the second end portion P2 extending along the third direction DR3 and the planar shape of the side surface of the intermediate portion extending along the third direction DR3 may be a straight line. In some implementations, the side surface extending along the third direction DR3 connecting the first end portion P1 or the second end portion P2 and the intermediate portion may be in a stepped shape. For example, the side surface of the first end portion P1 or the second end portion P2 extending along the third direction DR3 may have a form protruding in along the second direction DR2.

In the example of FIG. 5B, the plurality of active patterns 110 may have a shape extending in the third direction DR3 oblique to the first direction DR1 and the second direction DR2. For example, the first end portions P1 of the plurality of active patterns 110 may be spaced apart along the third direction DR3. For example, the third direction DR3 may be inclined at an angle between 35 degrees to 50 degrees with respect to the first direction DR1, but is not limited thereto.

In some implementations, the first end portions P1 of the plurality of active patterns 110 may be arranged along the second direction DR2. The second end portions P2 of the plurality of active patterns 110 may be arranged along the second direction DR2. The central portions P3 of the plurality of active patterns 110 may be arranged along the first direction DR1.

In some implementations, each active pattern 110 may have a shape extending in the third direction DR3. The active pattern 110 may have a length in the third direction DR3. The active pattern 110 may have a width in the second direction DR2.

In some implementations, the first end portion P1 and the second end portion P2 of the active pattern 110 may have a point-symmetrical shape with respect to the center of the active pattern 110. For example, the center of the active pattern 110 may mean the center of the length direction of the active pattern 110. For example, the planar shape of the first end portion P1 and the second end portion P2 may be a sector of a circle.

In some implementations, the width along the second direction DR2 of the first end portion P1 and the second end portion P2 of the active pattern 110 may be greater than the width along the second direction DR2 of the intermediate portion between the first end portion P1 and the second end portion P2. For example, the intermediate portion may mean a portion connecting the first end portion P1 and the second end portion P2. For example, the interval between both side surfaces of the first end portion P1 extending along the third direction DR3 and the interval between both side surfaces of the second end portion P2 extending along the third direction DR3 may be wider than the interval between both side surfaces of the intermediate portion extending along the third direction DR3.

In some implementations, the planar shape of the side surface of the first end portion P1 and the second end portion P2 extending along the third direction DR3 may be a curved line, and the planar shape of the side surface of the intermediate portion extending along the third direction DR3 may be a straight line.

For example, a first side surface of the first end portion P1 extending along the third direction DR3 may have the form protruding in the second direction DR2 more than first side surface of the intermediate portion connected thereto extending along the third direction DR3. First side surface of the intermediate portion extending along the third direction DR3 may form a plane with first side surface of the second end portion P2 connected thereto extending along the third direction DR3. Second side surface of the second end portion P2 extending along the third direction DR3 may protrude alone the second direction DR2 more than second side surface of the intermediate portion connected thereto extending along the third direction DR3. A second side surface of the intermediate portion extending along the third direction DR3 may form a plane with second side surface of the first end portion P1 connected thereto extending along the third direction DR3.

In the example of FIG. 5C, the plurality of active patterns 110 may have a shape extending in the third direction DR3 oblique to the first direction DR1 and the second direction DR2. For example, the first end portions P1 of the plurality of active patterns 110 may be spaced apart along the third direction DR3. For example, the third direction DR3 may be inclined at an angle between 35 degrees to 50 degrees with respect to the first direction DR1, but is not limited thereto.

In some implementations, the first end portions P1 of the plurality of active patterns 110 may be arranged along the second direction DR2. The second end portions P2 of the plurality of active patterns 110 may be arranged along the second direction DR2. The central portions P3 of the plurality of active patterns 110 may be arranged along the first direction DR1.

In some implementations, each active pattern 110 may have a shape extending in the third direction DR3. The active pattern 110 may have a length in the third direction DR3. The active pattern 110 may have a width in the second direction DR2.

In some implementations, the first end portion P1 and the second end portion P2 of the active pattern 110 may have a point-symmetrical shape with respect to the center of the active pattern 110. For example, the center of the active pattern 110 may mean the center of the length direction of the active pattern 110.

In some implementations, the width along the second direction DR2 of the first end portion P1 and the second end portion P2 of the active pattern 110 may be greater than the width along the second direction DR2 of the intermediate portion between the first end portion P1 and the second end portion P2. For example, the intermediate portion may mean a portion connecting the first end portion P1 and the second end portion P2. For example, the interval between both side surfaces of the first end portion P1 extending along the third direction DR3 and the interval between both side surfaces of the second end portion P2 extending along the third direction DR3 may be wider than the interval between both side surfaces of the intermediate portion extending along the third direction DR3.

In some implementations, the side surface of the first end portion P1 extending along the third direction DR3 and the second end portion P2 and the planar shape of the side surface of the intermediate portion extending along the third direction DR3 may be a continuous curved line. In some implementations, the side surface extending along the third direction DR3 connecting the first end portion P1 or the second end portion P2 and the intermediate portion may be a curved surface. For example, an interval of both side surfaces of the active pattern 110 extending along the third direction DR3 may be wider from the intermediate portion to the first end portion P1 or the second end portion P2.

In the example of FIG. 5D and FIG. 5E, the plurality of active patterns 110 may have a shape extending in the third direction DR3 oblique to the first direction DR1 and the second direction DR2. For example, the first end portions P1 of the plurality of active patterns 110 may be spaced apart along the third direction DR3. For example, the third direction DR3 may be inclined at an angle between 35 degrees to 50 degrees with respect to the first direction DR1, but is not limited thereto.

In some implementations, the first end portions P1 of the plurality of active patterns 110 may be arranged along the second direction DR2. The second end portions P2 of the plurality of active patterns 110 may be arranged along the second direction DR2. The central portions P3 of the plurality of active patterns 110 may be arranged along the first direction DR1.

In some implementations, each active pattern 110 may have a shape extending in the third direction DR3. The active pattern 110 may have a length in the third direction DR3.

In some implementations, the first end portion P1 and the second end portion P2 of the active pattern 110 may have a point-symmetrical shape with respect to the center of the active pattern 110. For example, the center of the active pattern 110 may mean the center of the length direction of the active pattern 110. For example, the planar shape of the first end portion P1 and the second end portion P2 may be a triangle or trapezoid.

In some implementations, the active pattern 110 may include at least one portion that is oblique to the first direction DR1 and the second direction DR2 and bent, e.g., changes directions from extending along the third direction to a fourth direction DR4 different from the third direction DR3. For example, the fourth direction DR4 may be perpendicular to the third direction DR3.

In some implementations, the portion bent in the fourth direction DR4 of the active pattern 110 may be positioned in the central portion P3 of the active pattern. For example, the first end portion P1 and the second end portion P2 may extend along the third direction DR3, and the central portion P3 positioned between the first end portion P1 and the second end portion P2 may be extended along the fourth direction DR4.

In some implementations shown in FIG. 5D, the first end portion P1 may be connected to an upper portion of the central portion P3 extending along the fourth direction DR4, and the second end portion P2 may be connected to a lower portion of the central portion P3 extending along the fourth direction DR4.

In some implementations shown in FIG. 5E, the first end portion P1 may be connected to the lower portion of the central portion P3 extending along the fourth direction DR4, and the second end portion P2 may be connected to the upper portion of the central portion P3 extending along the fourth direction DR4.

In the example of FIG. 5F, the plurality of active patterns 110 may have a shape extending in the third direction DR3 oblique to the first direction DR1 and the second direction DR2. For example, the first end portions P1 of the plurality of active patterns 110 may be spaced apart along the third direction DR3. For example, the third direction DR3 may be inclined at an angle between 35 degrees to 50 degrees with respect to the first direction DR1, but is not limited thereto.

In some implementations, the first end portions P1 of the plurality of active patterns 110 may be arranged along the second direction DR2. The second end portions P2 of the plurality of active patterns 110 may be arranged along the second direction DR2. The central portions P3 of the plurality of active patterns 110 may be arranged along the first direction DR1.

In some implementations, the active pattern 110 may include at least one the oblique to the first direction DR1 and the second direction DR2 and portion bent in the fourth direction DR4 different from the third direction DR3. For example, the fourth direction DR4 may cross the third direction DR3.

In some implementations, the portion bent in the fourth direction DR4 of the active pattern 110 may be positioned between the central portion P3 and the first end portion P1 of the active pattern or between the central portion P3 and the second end portion P2 of the active pattern. For example, the central portion P3 may extend in a direction different from the fourth direction DR4, and the first end portion P1 and the second end portion P2 may be extended along the fourth direction DR4. For example, the direction in which the central portion P3 extends may be different from the third direction DR3.

In some implementations, the first end portion P1 and the second end portion P2 of the active pattern 110 may have a point-symmetrical shape with respect to the center of the active pattern 110, but is not limited thereto. When the first end portion P1 and the second end portion P2 is not a point-symmetrical shape with respect to the center of the active pattern 110, a length of the first end portion P1 extending in the fourth direction DR4 and a length of the second end portion P2 extending in the fourth direction DR4 may be different from each other.

In the example of FIG. 5G and FIG. 5H, the plurality of active patterns 110 may have a shape extending in the third direction oblique to the first direction DR1 and the second direction DR2. For example, the first end portions P1 of the plurality of active patterns 110 may be spaced apart along the third direction DR3. For example, the third direction DR3 may be inclined at an angle between 35 degrees to 50 degrees with respect to the first direction DR1, but is not limited thereto.

In some implementations, the first end portions P1 of the plurality of active patterns 110 may be arranged along the second direction DR2. The second end portions P2 of the plurality of active patterns 110 may be arranged along the second direction DR2. The central portions P3 of the plurality of active patterns 110 may be arranged along the first direction DR1.

In some implementations, each active pattern 110 may have a shape extending in the third direction DR3. The active pattern 110 may have a length in the third direction DR3.

In some implementations, the first end portion P1 and the second end portion P2 of the active pattern 110 may have a point-symmetrical shape with respect to the center of the active pattern 110. For example, the center of the active pattern 110 may mean the center of the length direction of the active pattern 110.

In some implementations, in a plan view, both side surfaces of the active pattern 110 facing each other may include a recess RC, respectively. In some implementations, an inner side surface 115s of the recess RC may be a curved surface. In some implementations, recesses RC may face each other interposing the center of the active pattern 110. Two recess may be formed in one active pattern 110, but is not limited thereto.

In some implementations shown in FIG. 5G, the recess RC may be positioned on a first side surface 111 extending along the third direction DR3 and on a second side surface 113 extending from the first side surface and extending along the second direction DR2. For example, one recess RC may be formed at a portion where the first side surface 111 and the second side surface 113 meet. The inner side surface 115s of the recess RC may connect the first side surface 111 and the second side surface 113. For example, the first end portion P1 and the second end portion P2 may neighbor each recess RC in the second direction DR2.

In some implementations shown in FIG. 5H, the recess RC may be positioned on the side surface extending along the third direction DR3. For example, recesses RC may be formed on a first side surface extending along the third direction DR3 of the active pattern 110 and a second side surface facing the first side surface, respectively. The inner side surface 115s of the recess RC may connect a first portion and a second portion of side surfaces of the active pattern 110 extending in the third direction DR3 spaced apart by the recess RC. For example, the first end portion P1 and the second end portion P2 may neighbor each recess RC in the first direction DR1 and/or the third direction DR3.

In the example of FIG. 5I, the plurality of active patterns 110 may have a shape extending in the third direction DR3 oblique to the first direction DR1 and the second direction DR2. For example, the first end portions P1 of the plurality of active patterns 110 may be spaced apart along the third direction DR1. For example, the third direction DR3 may be inclined at an angle between 35 degrees to 50 degrees with respect to the first direction DR1, but is not limited thereto.

In some implementations, the first end portions P1 of the plurality of active patterns 110 may be arranged along the second direction DR2. The second end portions P2 of the plurality of active patterns 110 may be arranged along the second direction DR2. The central portions P3 of the plurality of active patterns 110 may be arranged along the first direction DR1.

In some implementations, the first end portion P1 and the second end portion P2 of the active pattern 110 may have a point-symmetrical shape with respect to the center of the active pattern 110. For example, the center of the active pattern 110 may mean the center of the length direction of the active pattern 110.

In some implementations, the active pattern 110 may have, in a plan view, a wavy shape having a uniform width in the second direction DR2. Both side surfaces facing each other in the second direction DR2 of the active pattern 110 may be a curved surface. An interval between both side surfaces facing each other in the second direction DR2 of the active pattern 110 may be the same over an entire length of the active pattern 110. For example, both side surfaces facing each other in the first direction DR1 of the active pattern 110 may be a flat surface.

For example, the first end portion P1 may be positioned at a point where the active pattern 110 of the wavy shape has highest height in the second direction DR2. The second end portion P2 may be positioned at a point where the active pattern 110 of the wavy shape has lowest height in the second direction DR2.

In some implementations, height differences in the second direction DR2 of the first end portion P1 and the second end portion P2 may be different from each other. In some implementations, the first end portion P1 and the second end portion P2 may have an angled shape. In this case, the active pattern 110 may have a zigzag shape when viewed in the first direction DR1.

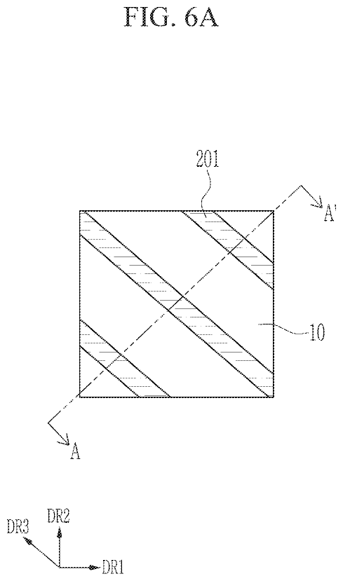

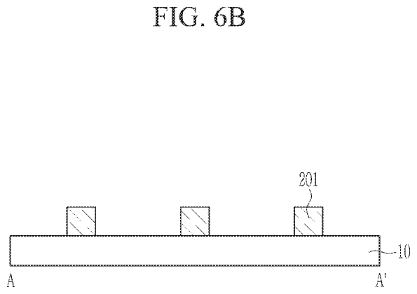

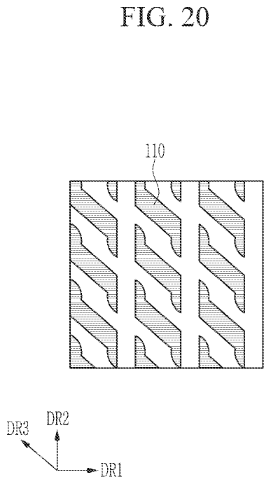

FIG. 6A to FIG. 20 are plan views and cross-sectional views showing an example of a process for patterning the active pattern 110. By the process shown in FIG. 6A to FIG. 19, the active patterns 110 shown in FIG. 20 may be formed.

Referring to FIG. 6A and FIG. 6B, auxiliary mask patterns 201 are formed on the substrate 10. FIG. 6B is a cross-sectional view taken along line A-A′ of FIG. 6A. The auxiliary mask pattern 201 may have a line shape extending along the third direction DR3. The auxiliary mask patterns 201 may be spaced apart at a regular interval.

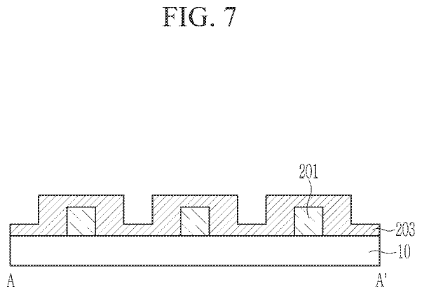

FIG. 7 shows a process after FIG. 6A and FIG. 6B, and shows a cross-section taken along the same direction as FIG. 6B. Referring to FIG. 7, a first mask layer 203 is formed. The first mask layer 203 may be formed, for example, by an atomic layer deposition (ALD) process. The first mask layer 203 may have a conformal shape. The first mask layer 203 may be disposed on an upper surface and a sidewall of the auxiliary mask patterns 201. The first mask layer 203 may be disposed on the upper surface of the substrate 10 positioned between the auxiliary mask patterns 201.

The first mask layer 203 may include, for example, a material having an etch selectivity with respect to the auxiliary mask pattern 201.

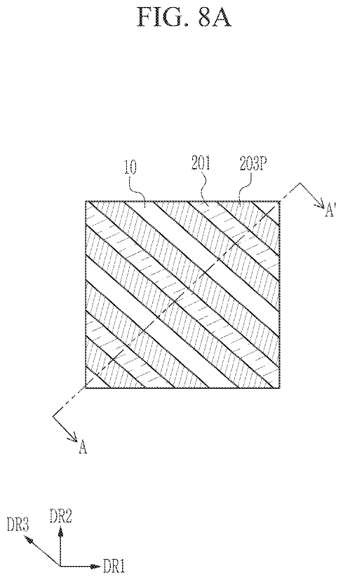

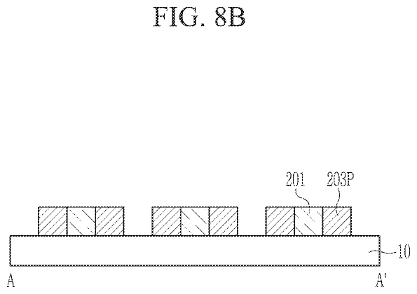

Subsequently, by etching at least a portion of the first mask layer 203, as shown in FIG. 8A and FIG. 8B, first mask patterns 203P is formed. FIG. 8B is a cross-sectional view taken along line A-A′ of FIG. 8A. For example, by using anisotropic etching process, the first mask layer 203 positioned on the upper surface of the substrate 10 and the auxiliary mask patterns 201 may be removed. Accordingly, the first mask layer 203 may remain only on both sides of the auxiliary mask patterns 201, and may be the first mask pattern 203P. For example, an upper surface of the first mask pattern 203P may be positioned at the same level with upper surfaces of the auxiliary mask pattern 201. A thickness of the first mask pattern 203P in the vertical direction may be the same as a thickness of the auxiliary mask pattern 201 in the vertical direction.

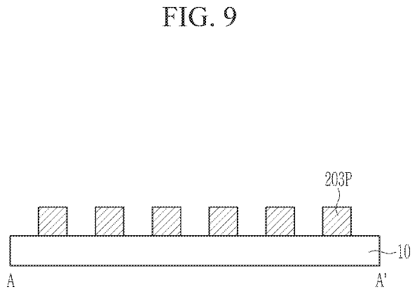

FIG. 9 shows a process after FIG. 8A and FIG. 8B, and shows a cross-section taken along the same direction as FIG. 8B. Referring to FIG. 9, the auxiliary mask patterns 201 is removed, and only the first mask patterns 203P remains. The auxiliary mask patterns 201 may be etched, for example, by a dry or wet etching process.

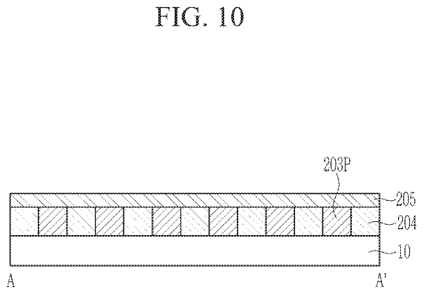

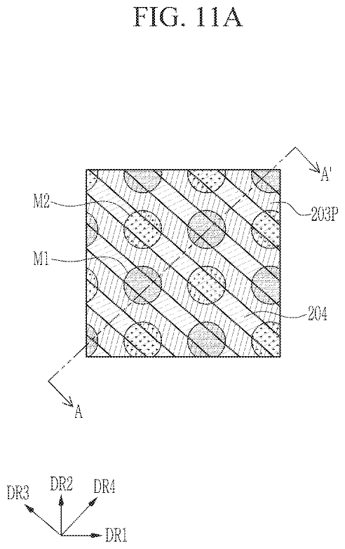

FIG. 10 shows a process after FIG. 9. Referring to FIG. 10, a first dummy layer 204 is formed. The first dummy layer 204 may be formed, for example, by a chemical vapor deposition (CVD) or physical vapor deposition (PVD) process. The first dummy layer 204 may include, for example, a material having an etch selectivity with respect to the first mask pattern 203P.

For example, the first dummy layer 204 may be deposited on the substrate 10 to fill a space between the first mask patterns 203P, and then etched at least partially by an etch back or CMP process. For example, the first dummy layer 204 may be etched such that an upper surface of the first dummy layer 204 may become flat with the upper surface of the first mask pattern 203P. Accordingly, the first dummy layer 204 and the first mask pattern 203P may be alternately disposed. Thereafter, a hard mask layer 205 may be formed on the first dummy layer 204 and the first mask patterns 203P.

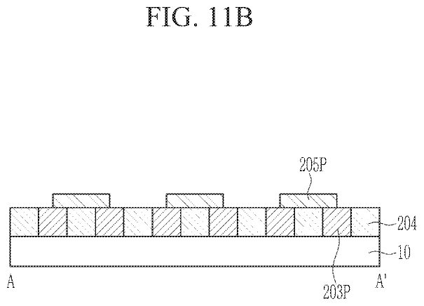

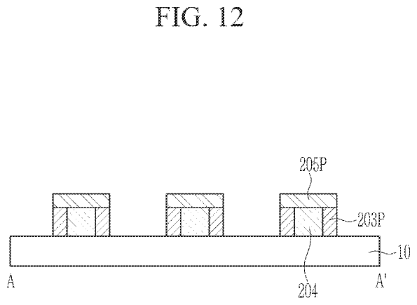

Referring to FIG. 11A and FIG. 11B, a hard mask pattern 205P is formed by patterning the hard mask layer 205. FIG. 11B is a cross-sectional view taken along line A-A′ of FIG. 11A. The hard mask pattern 205P may be formed through two or more processes. For example, the photoresist pattern may be formed by applying photoresist on the hard mask layer 205, and by processing a primary exposure and a secondary exposure and then developing. Subsequently, by using the photoresist pattern, the hard mask pattern 205P may be formed by etching the hard mask layer 205. The plan view of FIG. 11A illustrates that first portions M1 in which the hard mask layer 205 is removed by the primary exposure and second portions M2 in which the hard mask layer 205 is removed by the secondary exposure are distinguished, and for convenience, the hard mask pattern 205P is not illustrated in FIG. 11A. A mask used for the primary exposure and a mask used for the secondary exposure may be different or may be the same. For example, the secondary exposure process may be performed by shifting the mask used for the primary exposure.

The first portion M1 and a second portion M2 may be circular, in a plan view. The first portions M1 are spaced apart from each other along the third direction DR3 and the fourth direction DR4 perpendicular to the third direction DR3, and may have a repeating pattern. The second portions M2 are repeatedly arranged along the third direction DR3 and the fourth direction DR4 perpendicular to the third direction DR3, and may have a pattern disposed in a staggered manner with the first portions M1. The first portion M1 and the second portion M2 may be alternately disposed in the first direction DR1 and the second direction DR2.

FIG. 12 shows a process after FIG. 11A and FIG. 11B, and shows a cross-section taken along the same direction as FIG. 11B. Referring to FIG. 12, the etching process is performed by using the hard mask pattern 205P as an etch mask. The first dummy layer 204 and the first mask patterns 203P that are not covered by the hard mask pattern 205P may be removed. The first dummy layer 204 and the first mask patterns 203P that are covered by the hard mask pattern 205P may remain.

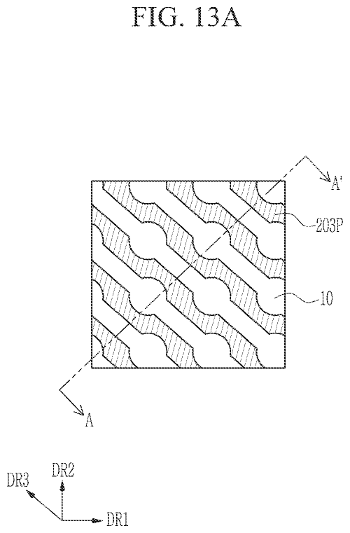

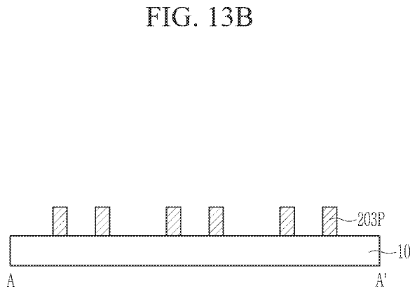

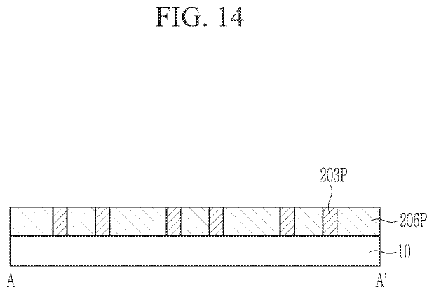

Referring to FIG. 13A and FIG. 13B, the hard mask pattern 205P and the remaining first dummy layer 204 are removed. FIG. 13B is a cross-sectional view taken along line A-A′ of FIG. 13A. For example, the hard mask pattern 205P may be removed first, and then the first dummy layer 204 may be removed. As another example, the hard mask pattern 205P and the first dummy layer 204 may be removed all at once.

For example, the hard mask pattern 205P and the first dummy layer 204 may be etched by a dry or wet etching process. The hard mask pattern 205P and the first dummy layer 204 may include a material having an etch selectivity with respect to the first mask pattern 203P. Accordingly, only the first mask patterns 203P may remain.

FIG. 14 shows a process after FIG. 13A and FIG. 13B, and shows a cross-section taken along the same direction as FIG. 13B. Referring to FIG. 14, second mask patterns 206P is formed. A second mask pattern 206P may include, for example, a material having an etch selectivity with respect to the first mask pattern 203P.

The second mask patterns 206P may be formed, for example, by a chemical vapor deposition (CVD) or physical vapor deposition (PVD) process. For example, the second mask layer may be deposited on an upper surface and a sidewall of the first mask patterns 203P, and the upper surface of the substrate 10, and then its upper surface may be etched at least partially by an etch back or CMP process. For example, the second mask layer may be etched such that an upper surface of the second mask pattern 206P may become flat with the upper surface of the first mask pattern 203P. Accordingly, a portion of the second mask layer positioned on the first mask pattern 203P may be removed, and a portion of the second mask layer positioned between the first mask patterns 203P may remain.

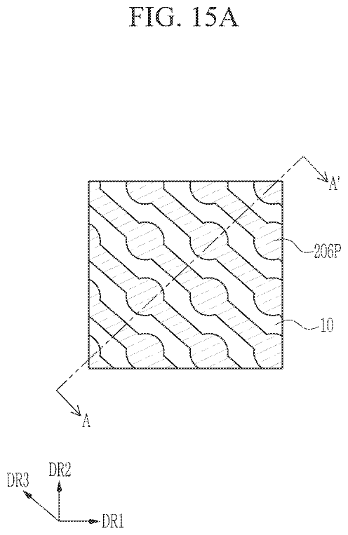

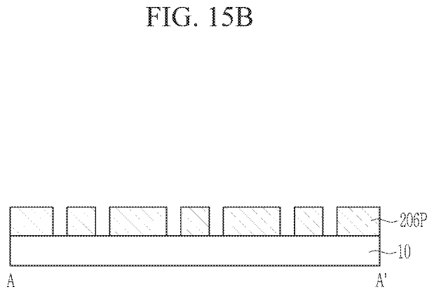

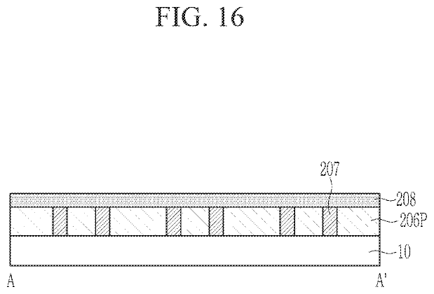

Referring to FIG. 15A and FIG. 15B, the first mask patterns 203P are removed. FIG. 15B is a cross-sectional view taken along line A-A′ of FIG. 15A. The first mask patterns 203P may be etched, for example, by a dry or wet etching process. As the first mask patterns 203P is removed, only the second mask patterns 206P may remain on the substrate 10. The remaining second mask patterns 206P may have an inverted pattern of the first mask patterns 203P.

FIG. 16 shows a process after FIG. 15A and FIG. 15B, and shows a cross-section taken along the same direction as FIG. 15B. Referring to FIG. 16, a second dummy layer 207 is formed. The second dummy layer 207 may be formed, for example, by a chemical vapor deposition (CVD) or physical vapor deposition (PVD) process. The second dummy layer 207 may include, for example, a material having an etch selectivity with respect to the second mask pattern 206P.

For example, the second dummy layer 207 may be deposited on an upper surface and a sidewall of the second mask patterns 206P, and the upper surface of the substrate 10, and then its upper surface may be etched at least partially by an etch back or CMP process. For example, the second dummy layer 207 may be etched such that an upper surface of the second dummy layer 207 may become flat with the upper surface of the second mask pattern 206P. Accordingly, the second dummy layer 207 may remain between the second mask patterns 206P. Thereafter, a photoresist layer 208 may be formed on the second dummy layer 207 and the second mask patterns 206P.

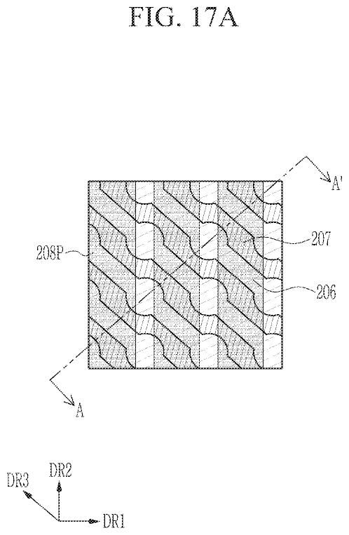

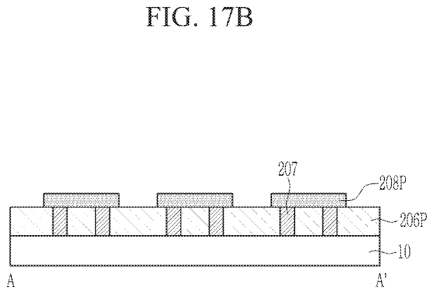

Referring to FIG. 17A and FIG. 17B, photoresist patterns 208P are formed by patterning the photoresist layer 208. FIG. 17B is a cross-sectional view taken along line A-A′ of FIG. 17A.

For example, the photoresist patterns 208P may be formed in line-shaped patterns extending in the second direction DR2. The line-shaped patterns may be disposed repeatedly and spaced apart along the first direction DR1.

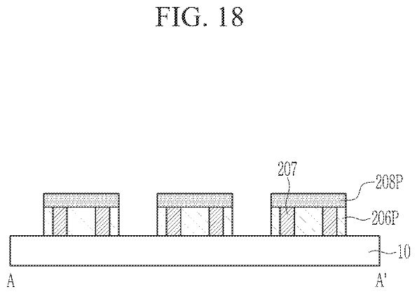

FIG. 18 shows a process after FIG. 17A and FIG. 17B, and shows a cross-section taken along the same direction as FIG. 17B. Referring to FIG. 18, the etching process is performed by using the photoresist patterns 208P as a mask. The second dummy layer 207 and the second mask patterns 206P that are not covered by the photoresist patterns 208P may be removed. The second dummy layer 207 and the second mask patterns 206P that are covered by the photoresist patterns 208P may remain.

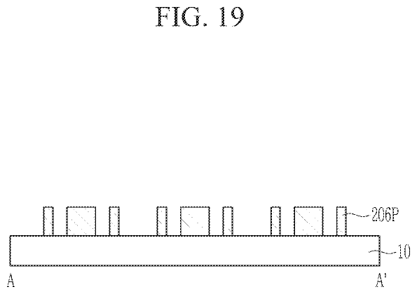

FIG. 19 shows a process after FIG. 18. Referring to FIG. 19, the photoresist patterns 208P and the remaining second dummy layer 207 are removed. For example, the photoresist patterns 208P may be removed first, and then the second dummy layer 207 may be removed. As another example, the photoresist patterns 208P and the second dummy layer 207 may be removed all at once.

For example, the photoresist patterns 208P may be removed by a strip process or an ashing process, and the second dummy layer 207 may be removed by a dry or wet etching process. The second dummy layer 207 may include a material having an etch selectivity with respect to the second mask pattern 206P. Accordingly, only the second mask patterns 206P may remain. The remaining second mask patterns 206P may correspond to the active patterns 110 of FIG. 20.

For example, after the processes shown in FIG. 6A to FIG. 19, a trench may be formed in an upper portion of the substrate 10 by using the remaining second mask patterns 206P as an etch mask. By disposing a device isolation pattern within the trench, the active patterns 110 of FIG. 20 may be defined. The active pattern 110 of FIG. 20 may be the active pattern 110 of FIG. 5B.

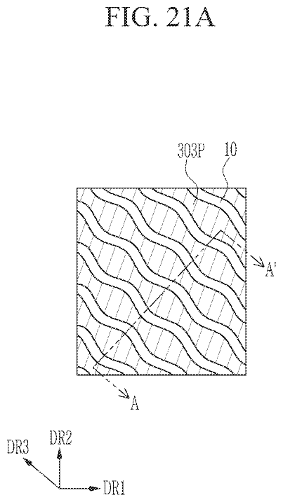

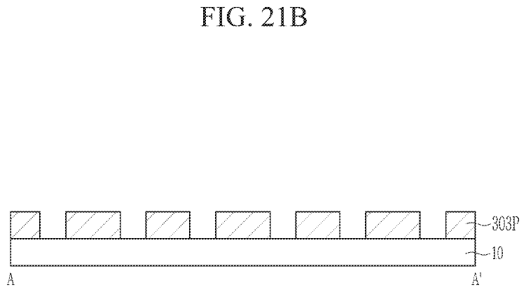

FIG. 21A to FIG. 25 are plan views and cross-sectional views showing an example of a process for patterning the active pattern 110. By the process shown in FIG. 21A to FIG. 24, the active patterns 110 shown in FIG. 25 may be formed.

Referring to FIG. 21A and FIG. 21B, mask patterns 303P may be formed on the substrate. FIG. 21B is a cross-sectional view taken along line A-A′ of FIG. 21A. The mask pattern 303P may extend along the third direction DR3, and may have a shape in which the interval between both side surfaces extending along the third direction DR3 repeatedly widens and narrows. Both side surfaces of the mask pattern 303P extending along the third direction DR3 may be a curved surface. The mask patterns 303P may be spaced apart at a regular interval.

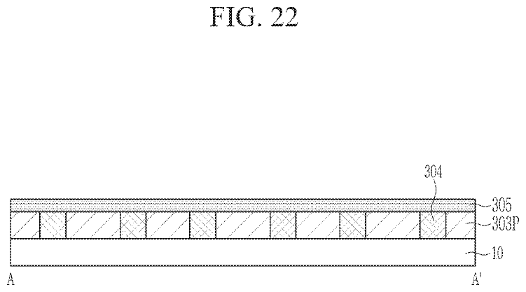

FIG. 22 shows a process after FIG. 21A and FIG. 21B, and shows a cross-section taken along the same direction as FIG. 21B. Referring to FIG. 22, a dummy layer 304 is formed. The dummy layer 304 may be formed, for example, by a chemical vapor deposition (CVD) or physical vapor deposition (PVD) process. The dummy layer 304 may include, for example, a material having an etch selectivity with respect to the mask pattern 303P.

For example, the dummy layer 304 may be deposited on an upper surface and a sidewall of the mask patterns 303P, and the upper surface of the substrate 10, and then its upper surface may be etched at least partially by an etch back or CMP process. For example, the dummy layer 304 may be etched such that an upper surface of the dummy layer 304 may become flat with an upper surface of the mask pattern 303P. Accordingly, the dummy layer 304 may remain between the mask patterns 303P. Thereafter, a photoresist layer 305 may be formed on the dummy layer 304 and the mask patterns 303P.

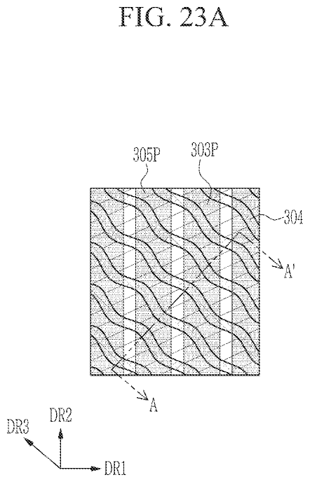

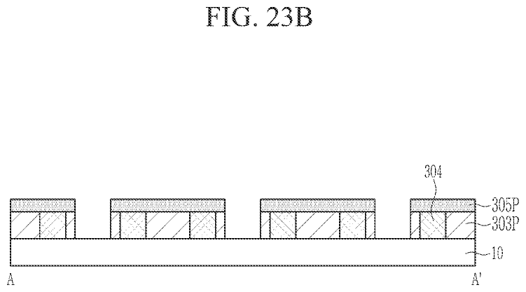

Referring to FIG. 23A and FIG. 23B, photoresist patterns 305P are formed by patterning the photoresist layer 305. FIG. 23B is a cross-sectional view taken along line A-A′ of FIG. 23A.

For example, the photoresist patterns 305P may be formed in line-shaped patterns extending in the second direction DR2. The line-shaped patterns may be disposed repeatedly and spaced apart along the first direction DR1.

Subsequently, the etching process may be performed by using the photoresist patterns 305P as a mask. The dummy layer 304 and the mask patterns 303P that are not covered by the photoresist patterns 305P may be removed. The dummy layer 304 and the mask patterns 303P that are covered by the photoresist patterns 305P may remain.

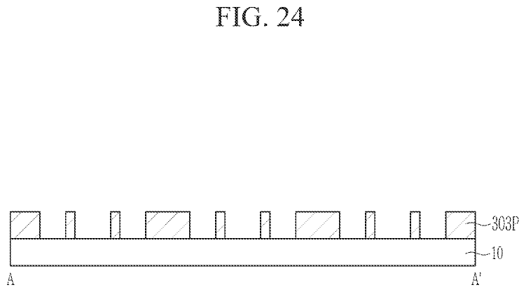

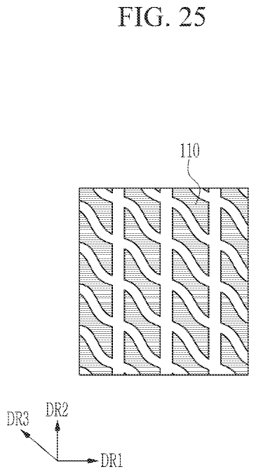

FIG. 24 shows a process after FIG. 23A and FIG. 23B. Referring to FIG. 24, the photoresist patterns 305P and the remaining dummy layer 304 are removed. For example, the photoresist patterns 305P may be removed first, and then the dummy layer 304 may be removed. As another example, the photoresist patterns 305P and the dummy layer 304 may be removed all at once.

For example, the photoresist patterns 305P may be removed by a strip process or an ashing process, and the dummy layer 304 may be removed by a dry or wet etching process. The dummy layer 304 may include a material having an etch selectivity with respect to the mask pattern 303P. Accordingly, only the mask patterns 303P may remain. The remaining mask patterns 303P may correspond to the active patterns 110 of FIG. 25.

For example, after the processes shown in FIG. 21A to FIG. 24, a trench may be formed in the upper portion of the substrate 10 by using the remaining mask patterns 303P as an etch mask. By disposing a device isolation pattern within the trench, the active patterns 110 of FIG. 25 may be defined. The active pattern 110 of FIG. 25 may be the active pattern 110 of FIG. 5C.

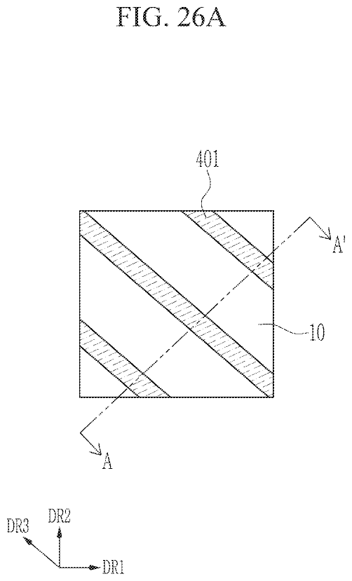

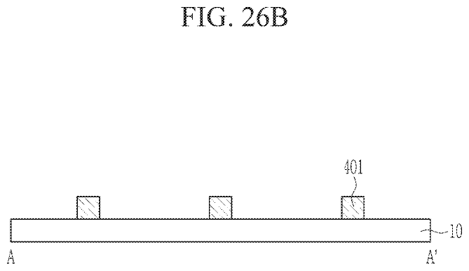

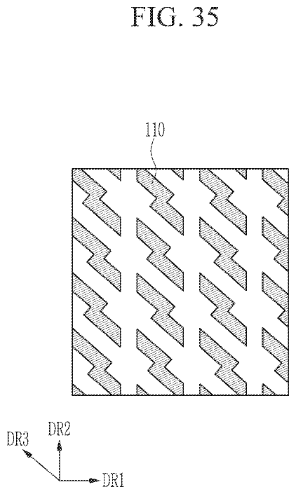

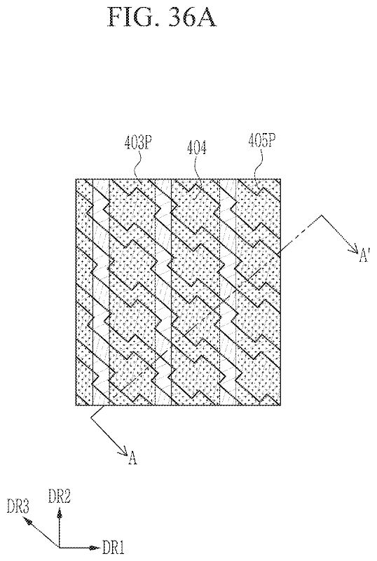

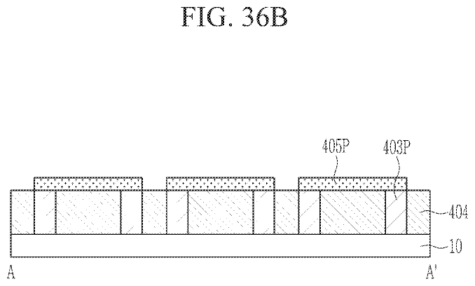

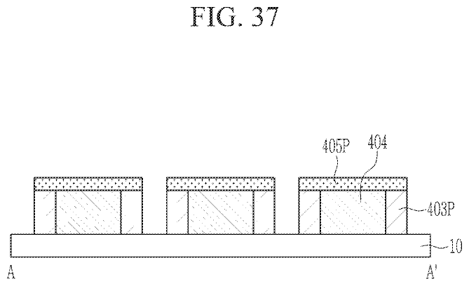

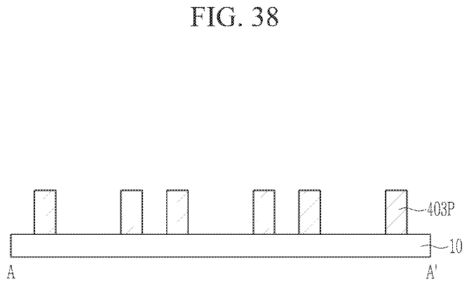

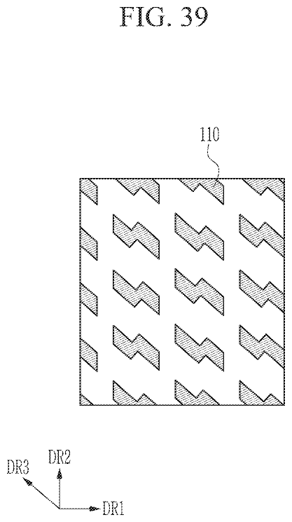

FIG. 26A to FIG. 39 are plan views and cross-sectional views showing an example of a process for patterning the active pattern 110. By the process shown in FIG. 26A to FIG. 34, the active patterns 110 shown in FIG. 35 may be formed. By the process shown in FIG. 26A to FIG. 31, and FIG. 36A to FIG. 38, the active patterns 110 shown in FIG. 39 may be formed.

Referring to FIG. 26A and FIG. 26B, first auxiliary mask patterns 401 are formed on the substrate 10. FIG. 26B is a cross-sectional view taken along line A-A′ of FIG. 26A. The first auxiliary mask pattern 401 may be in a line shape extending along the third direction DR3. The first auxiliary mask patterns 401 may be spaced apart at a regular interval.

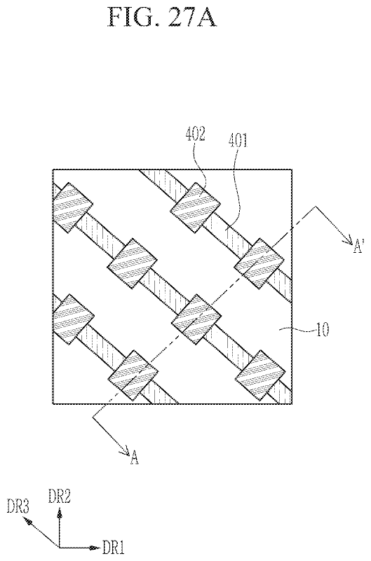

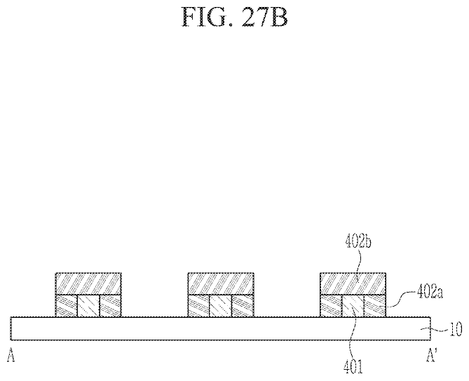

FIG. 27A and FIG. 27B show a process after FIG. 26A and FIG. 26B. Referring to FIG. 27A and FIG. 27B, second auxiliary mask patterns 402a and third auxiliary mask patterns 402b are formed.

For example, a first auxiliary mask layer may be deposited to cover the first auxiliary mask patterns 401 and the substrate 10, and an anisotropic etching process may be performed. Accordingly, the auxiliary mask layer covering the upper surfaces of the first auxiliary mask patterns 401 and the substrate 10 may be removed, and the auxiliary mask layer disposed on a sidewall of the first auxiliary mask patterns 401 may become flat with an upper surface of the first auxiliary mask pattern 401.

Thereafter, a second auxiliary mask layer may be deposited to cover the first auxiliary mask patterns 401 and the first auxiliary mask layer. The second auxiliary mask layer may include a material different from the first auxiliary mask layer. The photoresist pattern correspond to the third auxiliary mask patterns 402b may be formed by applying a photoresist layer on the second auxiliary mask layer and by exposing and developing the photoresist layer.

Thereafter, the second auxiliary mask patterns 402a and the third auxiliary mask patterns 402b may be formed by using the photoresist pattern. For example, the etching process may be performed by using the photoresist pattern as a mask. The second auxiliary mask layer that is not covered by the photoresist pattern is removed, such that the third auxiliary mask patterns 402b may be formed. The first auxiliary mask layer that is not covered by the photoresist pattern is removed, such that the second auxiliary mask patterns 402a may be formed.

The second auxiliary mask patterns 402a and the third auxiliary mask patterns 402b are distinguished in the above-described example, but in another example, the second auxiliary mask pattern 402a and the third auxiliary mask patterns 402b may be integrally formed.

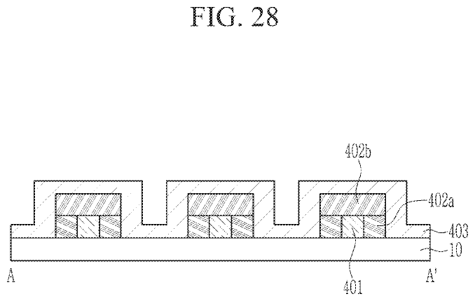

FIG. 28 shows a process after FIG. 27A and FIG. 27B, and shows a cross-section taken along the same direction as FIG. 27B. Referring to FIG. 28, a mask layer 403 may be formed. The mask layer 403 may be formed, for example, by an atomic layer deposition (ALD) process. The mask layer 403 may have a conformal shape. The mask layer 403 may be disposed on the upper surface and the sidewall of the first auxiliary mask patterns 401, a sidewall of the second auxiliary mask patterns 402a, and an upper surface and a sidewall of the third auxiliary mask patterns 402b. The mask layer 403 may be disposed on the upper surface of the substrate 10 positioned between the first auxiliary mask patterns 401 and the third auxiliary mask patterns 402b.

The mask layer 403 may include, for example, a material having an etch selectivity with respect to the first auxiliary mask pattern 401, the second auxiliary mask pattern 402a, and the third auxiliary mask pattern 402b.

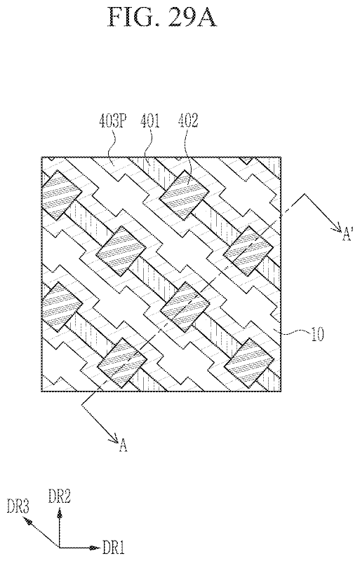

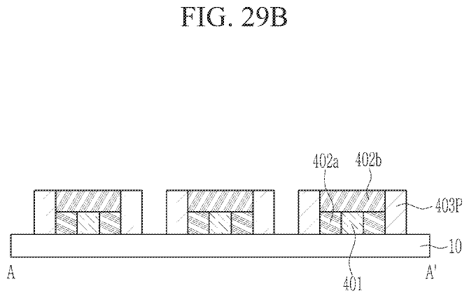

Subsequently, by etching at least a portion of the mask layer 403, as shown in FIG. 29A and FIG. 29B, mask patterns 403P may be formed. FIG. 29B is a cross-sectional view taken along line A-A′ of FIG. 29A. For example, by using anisotropic etching process, the mask layer 403 positioned on the first auxiliary mask patterns 401, the third auxiliary mask patterns 402b, and the upper surface of the substrate 10 may be removed. Accordingly, the mask layer 403 may remain only on both sides of the first auxiliary mask patterns 401, both sides of the second auxiliary mask patterns 402a, and both sides of the third auxiliary mask patterns 402b, and may be the mask pattern 403P. For example, an upper surface of the mask pattern 403P may be positioned at the same level with an upper surface of the first auxiliary mask pattern 401 or an upper surface of the third auxiliary mask pattern 402b. A thickness of the mask pattern 403P in the vertical direction may correspond to a thickness of the first auxiliary mask pattern 401 in the vertical direction, or correspond to a thickness of the third auxiliary mask pattern 402b in the vertical direction.

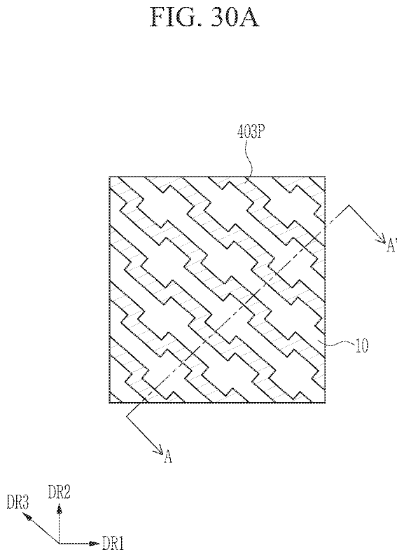

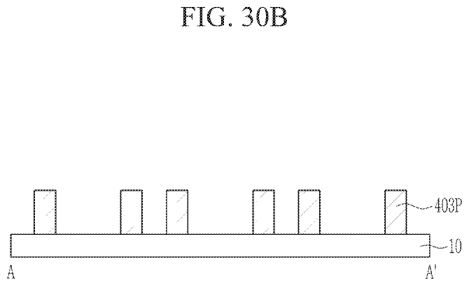

FIG. 30A and FIG. 30B show a process after FIG. 29A and FIG. 29B. Referring to FIG. 30A and FIG. 30B, the first auxiliary mask patterns 401, the second auxiliary mask patterns 402a, and the third auxiliary mask patterns 402b is removed, and only the mask patterns 403P remains. The first auxiliary mask patterns 401, the second auxiliary mask patterns 402a, and the third auxiliary mask patterns 402b may be etched, for example, by a dry or wet etching process.

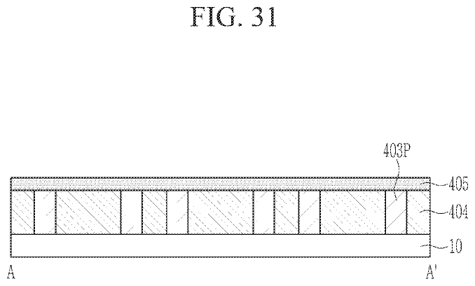

FIG. 31 shows a process after FIG. 30A and FIG. 30B. Referring to FIG. 31, a dummy layer 404 may be formed. The dummy layer 404 may include, for example, a material having an etch selectivity with respect to the mask pattern 403P.

The dummy layer 404 may be formed, for example, by a chemical vapor deposition (CVD) or physical vapor deposition (PVD) process. For example, the dummy layer 404 may be deposited on an upper surface and a sidewall of the mask patterns 403P, and the upper surface of the substrate 10, and then its upper surface may be etched at least partially by an etch back or CMP process. For example, the dummy layer 404 may be etched such that an upper surface of the dummy layer 404 may become flat with the upper surface of the mask pattern 403P. Accordingly, the dummy layer 404 may remain between the mask patterns 403P. Thereafter, a photoresist layer 405 may be formed on the dummy layer 404 and the mask patterns 403P.

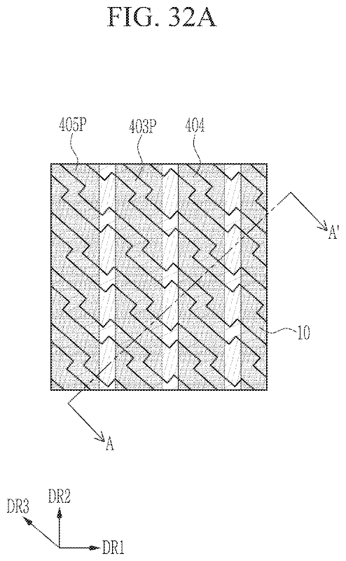

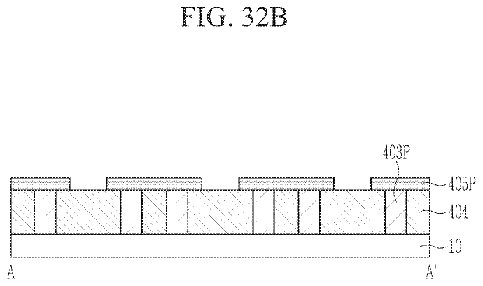

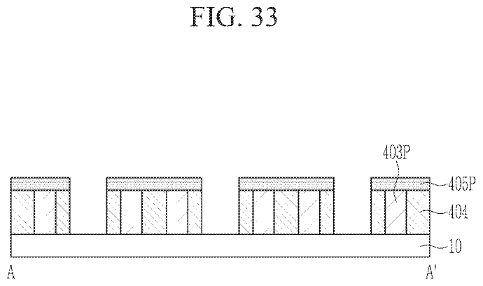

Referring to FIG. 32A and FIG. 32B, photoresist patterns 405P are formed by patterning the photoresist layer 405. FIG. 32B is a cross-sectional view taken along line A-A′ of FIG. 32A.

For example, the photoresist patterns 405P may be formed in line-shaped patterns extending in the second direction DR2. The line-shaped patterns may be disposed repeatedly and spaced apart along the first direction DR1.

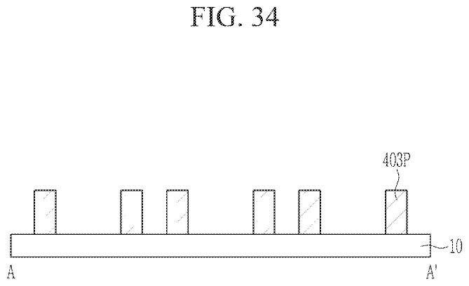

FIG. 33 shows a process after FIG. 32A and FIG. 32B, and shows a cross-section taken along the same direction as FIG. 32B. Referring to FIG. 33, the etching process may be performed by using the photoresist patterns 405P as a mask. The dummy layer 404 and the mask patterns 403P that are not covered by the photoresist patterns 405P may be removed. The dummy layer 404 and the mask patterns 403P that are covered by the photoresist patterns 405P may remain.

FIG. 34 shows a process after FIG. 33. Referring to FIG. 34, the photoresist patterns 405P and the remaining dummy layer 404 may be removed. For example, the photoresist patterns 405P may be removed first, and then the dummy layer 404 may be removed. As another example, the photoresist patterns 405P and the dummy layer 404 may be removed all at once.

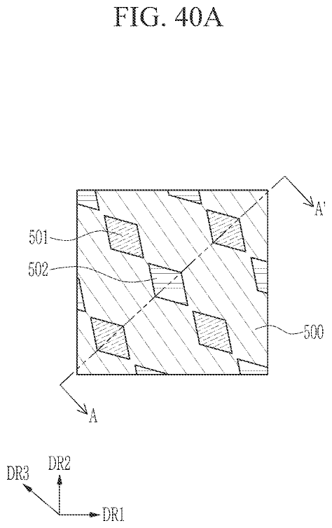

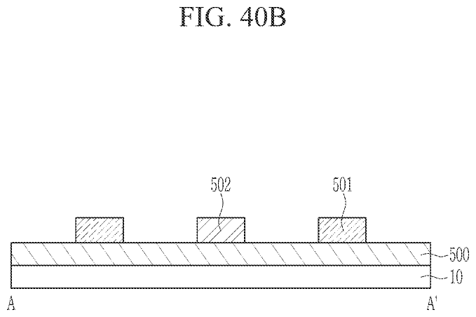

For example, the photoresist patterns 405P may be removed by a strip process or an ashing process, and the dummy layer 404 may be removed by a dry or wet etching process. The dummy layer 404 may include a material having an etch selectivity with respect to the mask pattern 403P. Accordingly, only the mask patterns 403P may remain. The remaining mask patterns 403P may correspond to the active patterns 110 of FIG. 40.

For example, after the processes shown in FIG. 26A to FIG. 34, a trench may be formed in the upper portion of the substrate 10 by using the remaining mask patterns 403P as an etch mask. By disposing a device isolation pattern within the trench, the active patterns 110 of FIG. 40 may be defined. The active pattern 110 of FIG. 35 may be the active pattern 110 of FIG. 5D.

The process of FIG. 36A and FIG. 36B may correspond to process of FIG. 32A and FIG. 32B. For example, after performing the process of FIG. 31, the process of FIG. 36A and FIG. 36B may be performed.

Referring to FIG. 36A and FIG. 36B, the photoresist patterns 405P are formed by patterning the photoresist layer 405. FIG. 36B is a cross-sectional view taken along line A-A′ of FIG. 36A.

For example, the photoresist patterns 405P may be formed in line-shaped patterns extending in the second direction DR2. The line-shaped patterns may be disposed repeatedly and spaced apart along the first direction DR1. For example, in order to form the photoresist patterns 405P of FIG. 36A and FIG. 36B, the exposure process may be performed by shifting the photomask for forming the photoresist patterns 405P of FIG. 32A and FIG. 32B in the first direction DR1.

FIG. 37 shows a process after FIG. 36A and FIG. 36B, and shows a cross-section taken along the same direction as FIG. 36B. Referring to FIG. 37, the etching process may be performed by using the photoresist patterns 405P as a mask. The dummy layer 404 and the mask patterns 403P that are not covered by the photoresist patterns 405P may be removed. The dummy layer 404 and the mask patterns 403P that are covered by the photoresist patterns 405P may remain.

FIG. 38 shows a process after FIG. 37. Referring to FIG. 38, the photoresist patterns 405P and the remaining dummy layer 404 may be removed. For example, the photoresist patterns 405P may be removed first, and then the dummy layer 404 may be removed. As another example, the photoresist patterns 405P and the dummy layer 404 may be removed all at once.

For example, the photoresist patterns 405P may be removed by a strip process or an ashing process, and the dummy layer 404 may be etched by a dry or wet etching process. The dummy layer 404 may include a material having an etch selectivity with respect to the mask pattern 403P. Accordingly, only the mask patterns 403P may remain. The remaining mask patterns 403P may correspond to the active patterns 110 of FIG. 39.

For example, after the processes shown in FIG. 26A to FIG. 31 and FIG. 36A to FIG. 38, a trench may be formed in the upper portion of the substrate 10 by using the remaining mask patterns 403P as an etch mask. By disposing a device isolation pattern within the trench, the active patterns 110 of FIG. 39 may be defined. The active pattern 110 of FIG. 39 may be the active pattern 110 of FIG. 5E.

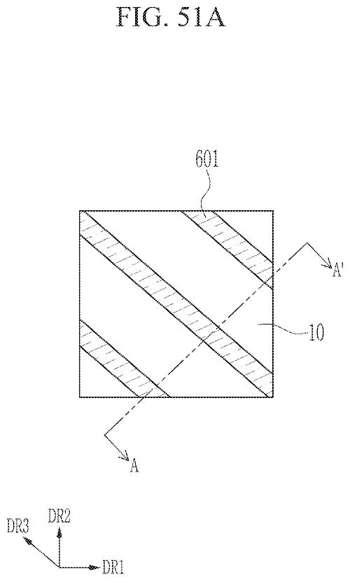

FIG. 40A to FIG. 50 are plan views and cross-sectional views showing an example of a process for patterning the active pattern 110. By the process shown in FIG. 40A to FIG. 49, the active patterns 110 shown in FIG. 50 may be formed.

Referring to FIG. 40A and FIG. 40B, a first mask layer 500 is formed on the substrate 10, and first auxiliary mask patterns 501 and second auxiliary mask patterns 502 may be formed on the first mask layer 500. FIG. 40B is a cross-sectional view taken along line A-A′ of FIG. 40A. The first auxiliary mask pattern 501 and the second auxiliary mask pattern 502 may have a rhombus with the diagonal aligned in the third direction DR3, respectively. The first auxiliary mask patterns 501 and the second auxiliary mask patterns 502 may be spaced apart by a regular interval along the third direction DR3. The second auxiliary mask patterns 502 may be disposed in a staggered manner with the first auxiliary mask patterns 501. The first auxiliary mask pattern 501 and the second auxiliary mask pattern 502 may be alternately disposed along the third direction DR3. The first auxiliary mask pattern 501 and the second auxiliary mask pattern 502 neighboring in the third direction DR3 may be spaced apart by a preset interval.

The first auxiliary mask pattern 501 may be formed first by using hard mask layer, and the second auxiliary mask pattern 502 may be sequentially formed. Double patterning technology may be applied when forming the first auxiliary mask pattern 501 and the second auxiliary mask pattern 502.

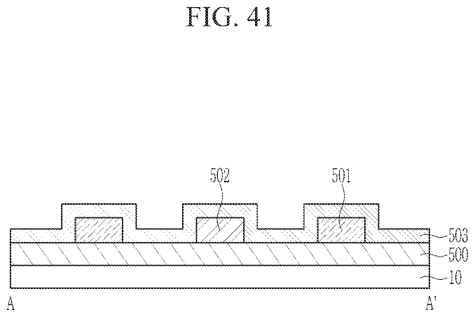

FIG. 41 shows a process after FIG. 40A and FIG. 40B, and shows a cross-section taken along the same direction as FIG. 40B. Referring to FIG. 41, a first dummy layer 503 is formed. The first dummy layer 503 may be formed, for example, by an atomic layer deposition (ALD) process. The first dummy layer 503 may have a conformal shape. The first dummy layer 503 may be disposed on upper surfaces and sidewalls of the first auxiliary mask patterns 501 and the second auxiliary mask patterns 502. The first dummy layer 503 may be disposed on upper surface of the first mask layer 500 positioned between the first auxiliary mask patterns 501 and the second auxiliary mask patterns 502. For example, the first dummy layer 503 may be disposed between the first auxiliary mask pattern 501 and the second auxiliary mask pattern 502 neighboring in the third direction DR3.

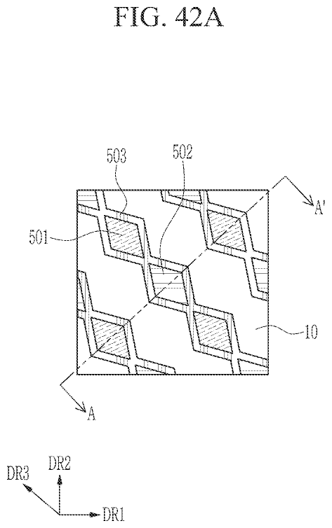

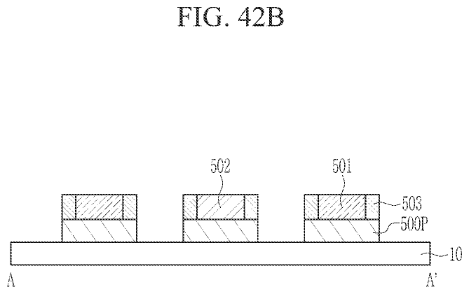

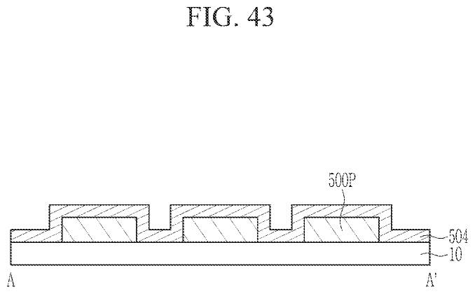

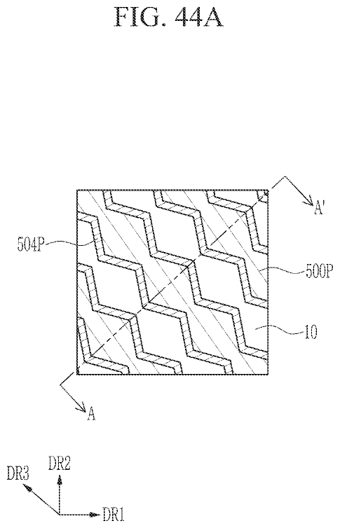

Referring to FIG. 42A and FIG. 42B, at least a portion of the first dummy layer 503 may be etched. FIG. 42B is a cross-sectional view taken along line A-A′ of FIG. 42A. For example, by using anisotropic etching process, the first dummy layer 503 positioned on upper surfaces of the first auxiliary mask patterns 501, the second auxiliary mask patterns 502, and the first mask layer 500 may be removed. Accordingly, the first dummy layer 503 may remain only on both sides of the first auxiliary mask patterns 501 and both sides of the second auxiliary mask patterns 502. For example, an upper surface of the first dummy layer 503 may be positioned at the same level with an upper surface of the first auxiliary mask pattern 501 and/or an upper surface of the second auxiliary mask pattern 502. A thickness of the first dummy layer 503 in the vertical direction may correspond to a thickness of the first auxiliary mask pattern 501 in the vertical direction and/or a thickness of the second auxiliary mask pattern 502 in the vertical direction. Thereafter, the etching process may be performed by using the first auxiliary mask pattern 501, the second auxiliary mask pattern 502, and the first dummy layer 503 as masks. The first mask layer 500 that is not covered by the first auxiliary mask pattern 501, the second auxiliary mask pattern 502, and the first dummy layer 503 may be removed such that first mask patterns 500P may be formed.

FIG. 43 shows a process after FIG. 42A and FIG. 42B, and shows a cross-section taken along the same direction as FIG. 42B. Referring to FIG. 43, a second mask layer 504 is formed. The second mask layer 504 may be formed, for example, by an atomic layer deposition (ALD) process. The second mask layer 504 may have a conformal shape. The second mask layer 504 may be disposed on an upper surface and a sidewall of the first mask patterns 500P. The second mask layer 504 may be disposed on the upper surface of the substrate 10 positioned between sidewalls of the first mask patterns 500P.

The second mask layer 504 may include, for example, a material having an etch selectivity with respect to the first mask pattern 500P.

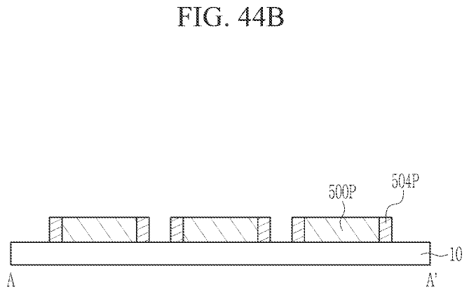

Subsequently, by etching at least a portion of the second mask layer 504, as shown in FIG. 44A and FIG. 44B, second mask patterns 504P may be formed. FIG. 44B is a cross-sectional view taken along line A-A′ of FIG. 44A. For example, by using anisotropic etching process, the second mask layer 504 positioned on the upper surface of the first mask pattern 500P and the substrate 10 may be removed. Accordingly, the second mask layer 504 may remain only on the sidewall of the first mask patterns 500P, to form the second mask pattern 504P. For example, an upper surface of the second mask pattern 504P may be positioned at the same level with the upper surface of the first mask pattern 500P. A thickness of the second mask pattern 504P in the vertical direction may correspond to a thickness of the first mask pattern 500P in the vertical direction.

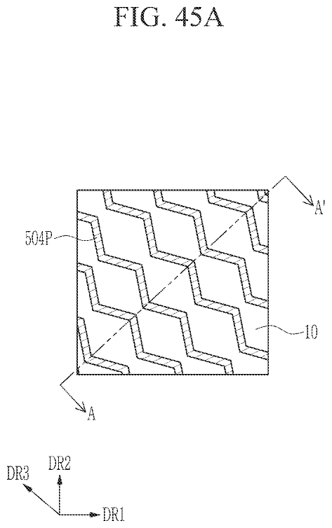

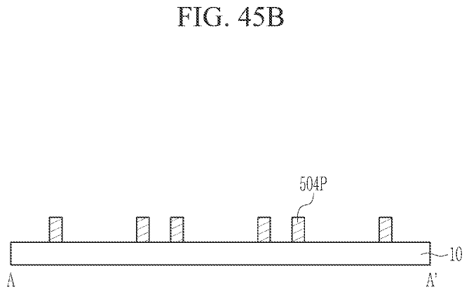

FIG. 45A and FIG. 45B show a process after FIG. 44A and FIG. 44B. Referring to FIG. 45A and FIG. 45B, the first mask pattern 500P is removed, and only the second mask patterns 504P remains. The first mask pattern 500P may be etched, for example, by a dry or wet etching process.

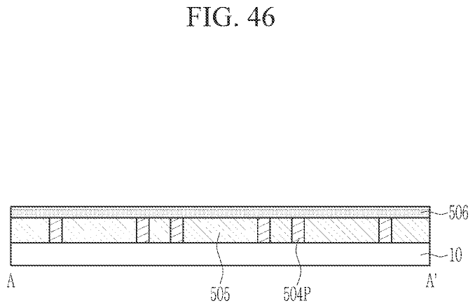

FIG. 46 shows a process after FIG. 45A and FIG. 45B, and shows a cross-section taken along the same direction as FIG. 45B. Referring to FIG. 46, a second dummy layer 505 may be formed. The second dummy layer 505 may include, for example, a material having an etch selectivity with respect to the second mask pattern 504P.

The second dummy layer 505 may be formed, for example, by a chemical vapor deposition (CVD) or physical vapor deposition (PVD) process. For example, the second dummy layer 505 may be deposited on an upper surface and a sidewall of the second mask patterns 504P, and the upper surface of the substrate 10, and then etch, at least partially, an upper surface through an etch back or CMP process. For example, the second dummy layer 505 may be etched such that an upper surface of the second dummy layer 505 may become flat with the upper surface of the second mask pattern 504P. Accordingly, the second dummy layer 505 may remain between the second mask patterns 504P. Thereafter, a photoresist layer 506 may be formed on the second dummy layer 505 and the second mask patterns 504P.

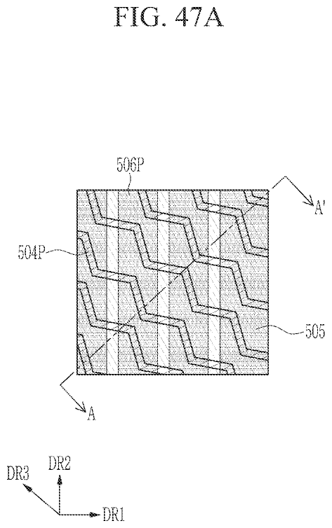

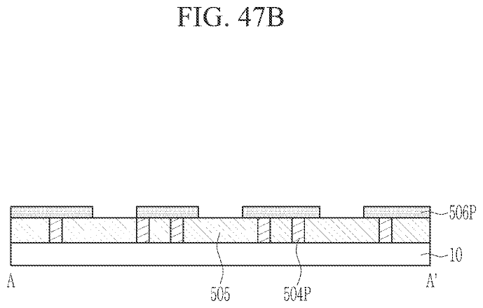

Referring to FIG. 47A and FIG. 47B, photoresist patterns 506P are formed by patterning the photoresist layer 506. FIG. 47B is a cross-sectional view taken along line A-A′ of FIG. 47A.

For example, the photoresist patterns 506P may be formed in line-shaped patterns extending in the second direction DR2. The line-shaped patterns may be disposed repeatedly and spaced apart along the first direction DR1.

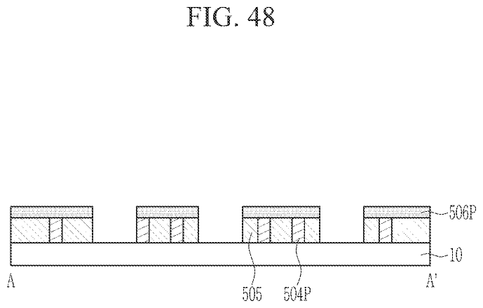

FIG. 48 shows a process after FIG. 47A and FIG. 47B, and shows a cross-section taken along the same direction as FIG. 47B. Referring to FIG. 48, the etching process may be performed by using the photoresist patterns 506P as a mask. The second dummy layer 505 and the second mask patterns 504P that are not covered by the photoresist patterns 506P may be removed. The second dummy layer 505 and the second mask patterns 504P that are covered by the photoresist patterns 506P may remain.

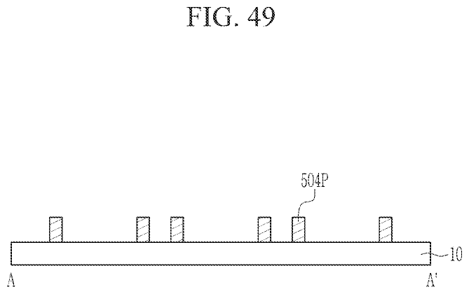

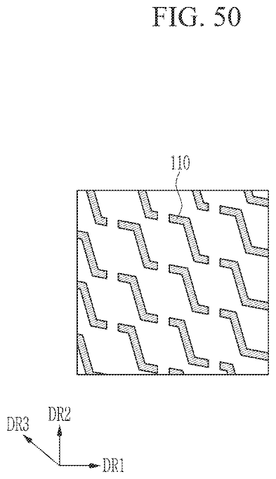

FIG. 49 shows a process after FIG. 48. Referring to FIG. 49, the photoresist patterns 506P and the remaining second dummy layer 505 may be removed. For example, the photoresist patterns 506P may be removed first, and then the second dummy layer 505 may be removed. As another example, the photoresist patterns 506P and the second dummy layer 505 may be removed all at once.

For example, the photoresist patterns 506P may be removed by a strip process or an ashing process, and the second dummy layer 505 may be removed by a dry or wet etching process. The second dummy layer 505 may include a material having an etch selectivity with respect to the second mask pattern 504P. Accordingly, only the second mask patterns 504P may remain. The remaining second mask patterns 504P may correspond to the active patterns 110 of FIG. 50.

For example, after the processes shown in FIG. 40A to FIG. 49, a trench may be formed in the upper portion of the substrate 10 by using the remaining second mask patterns 504P as an etch mask. By disposing a device isolation pattern within the trench, the active patterns 110 of FIG. 50 may be defined. The active pattern 110 of FIG. 50 may be the active pattern 110 of FIG. 5F.

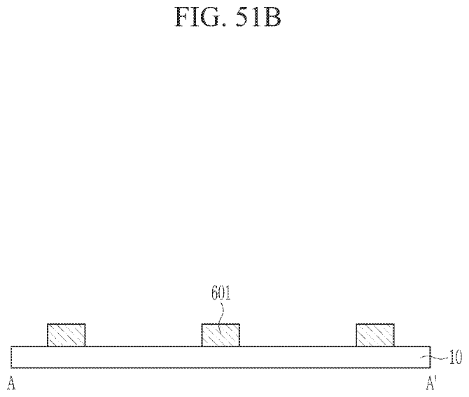

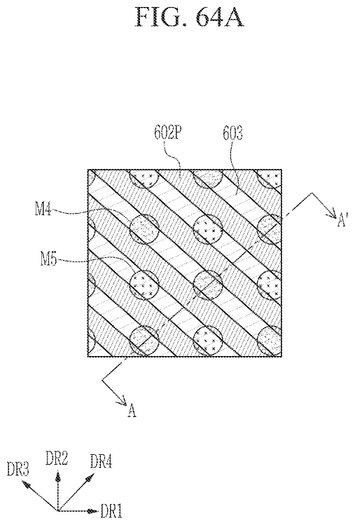

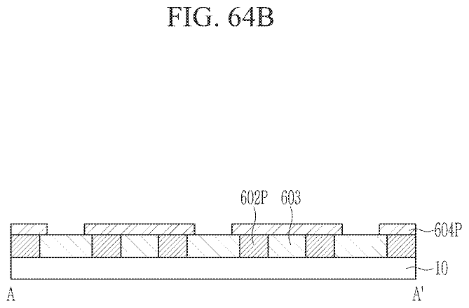

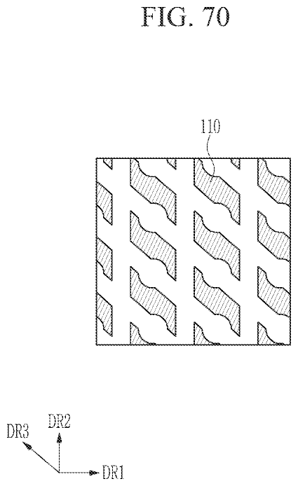

FIG. 51A to FIG. 70 are plan views and cross-sectional views showing an example of a process for patterning the active pattern 110. By the process shown in FIG. 51A to FIG. 62, the active patterns 110 shown in FIG. 63 may be formed. By the process shown in FIG. 51A to FIG. 55, and FIG. 64A to FIG. 70, the active patterns 110 shown in FIG. 70 may be formed.

In the example of FIG. 51A and FIG. 51B, auxiliary mask patterns 601 are formed on the substrate 10. FIG. 51B is a cross-sectional view taken along line A-A′ of FIG. 51A. The auxiliary mask pattern 601 may be a line shape extending along the third direction DR3. The auxiliary mask patterns 601 may be spaced apart at a regular interval.

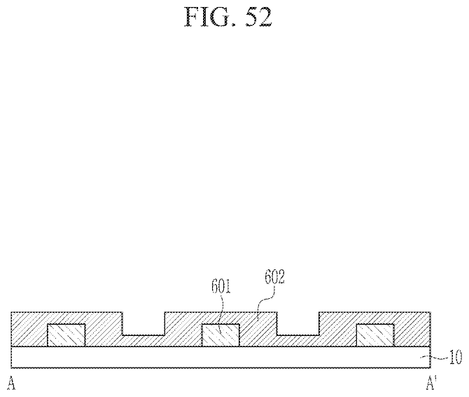

FIG. 52 shows a process after FIG. 51A and FIG. 51B, and shows a cross-section taken along the same direction as FIG. 51A. In the example of FIG. 52, a mask layer 602 may be formed. The mask layer 602 may be formed, for example, by an atomic layer deposition (ALD) process. The mask layer 602 may have a conformal shape. The mask layer 602 may be disposed on an upper surface and a sidewall of the auxiliary mask patterns 601. The mask layer 602 may be disposed on the upper surface of the substrate 10 positioned between the auxiliary mask patterns 601.

The mask layer 602 may include, for example, a material having an etch selectivity with respect to the auxiliary mask pattern 601.

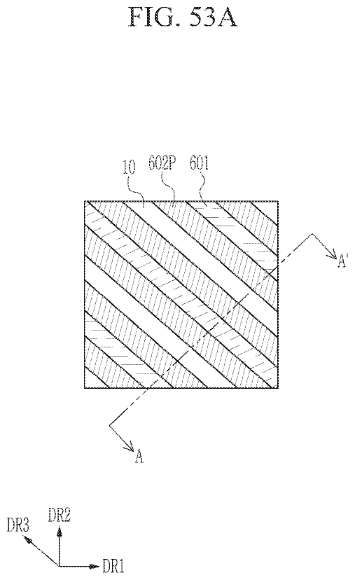

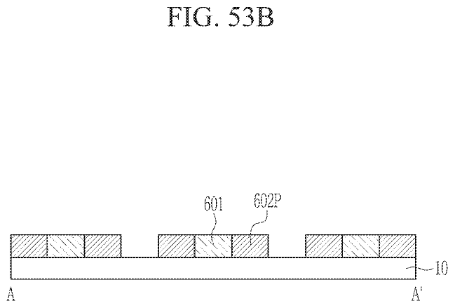

Subsequently, by etching at least a portion of the mask layer 602, as shown in FIG. 53A and FIG. 53B, mask patterns 602P may be formed. FIG. 53B is a cross-sectional view taken along line A-A′ of FIG. 53A. For example, by using anisotropic etching process, the mask layer 602 positioned on upper surfaces of the auxiliary mask patterns 601 and the substrate 10 may be removed. Accordingly, the mask layer 602 may remain only on both sides of the auxiliary mask patterns 601, and may be the mask pattern 602P. For example, an upper surface of the mask pattern 602P may be positioned at the same level with upper surfaces of the auxiliary mask pattern 601. A thickness of the mask pattern 602P in the vertical direction may correspond to a thickness of the auxiliary mask pattern 601 in the vertical direction.

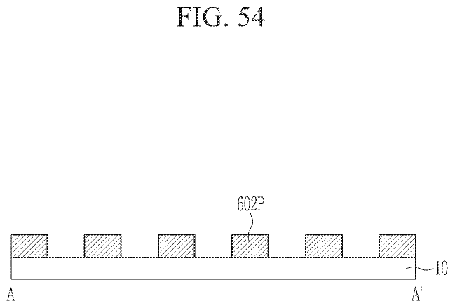

FIG. 54 shows a process after FIG. 53A and FIG. 53B, and shows a cross-section taken along the same direction as FIG. 53B. In the example of FIG. 54, the auxiliary mask patterns 601 is removed, and only the mask patterns 602P remains. The auxiliary mask patterns 601 may be etched, for example, by a dry or wet etching process.

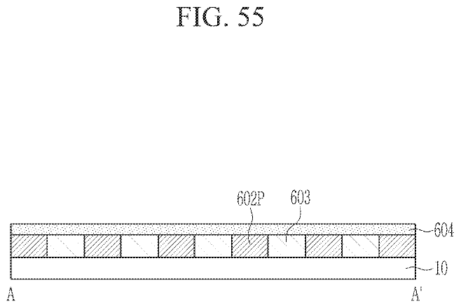

FIG. 55 shows a process after FIG. 54. In the example of FIG. 55, a first dummy layer 603 is formed. The first dummy layer 603 may include, for example, a material having an etch selectivity with respect to the mask pattern 602P.

The first dummy layer 603 may be formed, for example, by a chemical vapor deposition (CVD) or physical vapor deposition (PVD) process. For example, the first dummy layer 603 may be deposited on the substrate 10 to fill a space between the mask patterns 602P, and then its upper surface may be etched at least partially by an etch back or CMP process. For example, the first dummy layer 603 may be etched such that an upper surface of the first dummy layer 603 may become flat with the upper surface of the mask pattern 602P. Accordingly, the first dummy layer 603 and the mask pattern 602P may be alternately disposed. Thereafter, a hard mask layer 604 may be formed on the first dummy layer 603 and the mask patterns 602P.

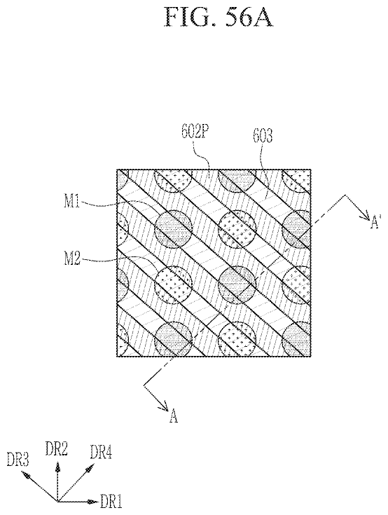

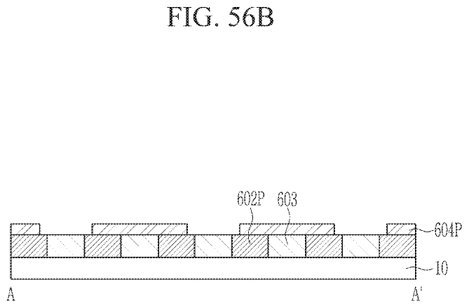

In the example of FIG. 56A and FIG. 56B, a hard mask pattern 604P may be formed by patterning the hard mask layer 604. FIG. 56B is a cross-sectional view taken along line A-A′ of FIG. 56A. The hard mask pattern 604P may be formed through two or more processes. For example, by applying photoresist on the hard mask layer 604, and the photoresist pattern may be formed by processing a primary exposure and a secondary exposure and then developing. Subsequently, by using the photoresist pattern, the hard mask pattern 604P may be formed by etching the hard mask layer 604. The plan view of FIG. 56A illustrates that first portions M1 in which the hard mask layer 604 is removed by the primary exposure and second portions M2 in which the hard mask layer 604 is removed by the secondary exposure are distinguished, and for convenience, the hard mask pattern 604P is not illustrated in FIG. 56A. A mask used for the primary exposure and a mask used for the secondary exposure may be different or may be the same. For example, the secondary exposure process may be performed by shifting the mask used for the primary exposure.

The first portion M1 and the second portion M2 may be circular, in a plan view. The first portions M1 are spaced apart from each other along the third direction DR3 and the fourth direction DR4 perpendicular to the third direction DR3, and may have a repeating pattern. The second portions M2 are repeatedly arranged along the third direction DR3 and the fourth direction DR4 perpendicular to the third direction, and may have a pattern disposed in a staggered manner with the first portions M1. The first portion M1 and the second portion M2 may be alternately disposed in the first direction DR1 and the second direction DR2.

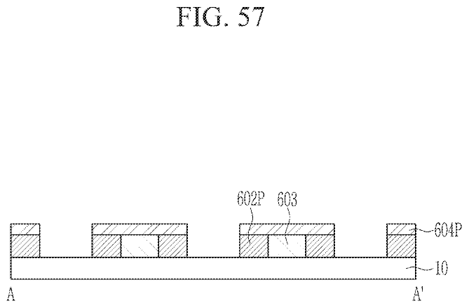

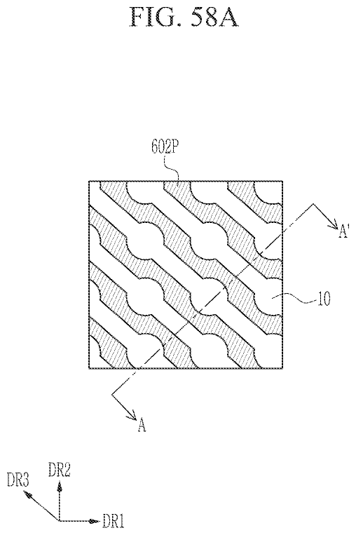

FIG. 57 shows a process after FIG. 56A and FIG. 56B, and shows a cross-section taken along the same direction as FIG. 56B. In the example of FIG. 57, the etching process may be performed by using the hard mask pattern 604P as an etch mask. The first dummy layer 603 and the mask patterns 602P that are not covered by the hard mask pattern 604P may be removed. The first dummy layer 603 and the mask patterns 602P that are covered by the hard mask pattern 604P may remain.

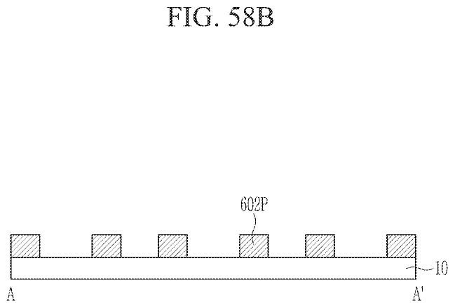

In the example of FIG. 58A and FIG. 58B, the hard mask pattern 604P and the remaining first dummy layer 603 may be removed. FIG. 58B is a cross-sectional view taken along line A-A′ of FIG. 58A. For example, the hard mask pattern 604P may be removed first, and then the first dummy layer 603 may be removed. As another example, the hard mask pattern 604P and the first dummy layer 603 may be removed all at once.

For example, the hard mask pattern 604P and the first dummy layer 603 may be etched by a dry or wet etching process. The hard mask pattern 604P and the first dummy layer 603 may include a material having an etch selectivity with respect to the mask pattern 602P. Accordingly, only the mask patterns 602P may remain.

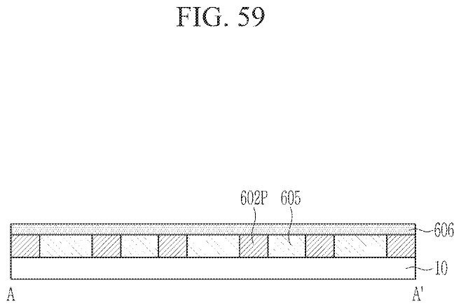

FIG. 59 shows a process after FIG. 58A and FIG. 58B, and shows a cross-section taken along the same direction as FIG. 58B. In the example of FIG. 59, a second dummy layer 605 may be formed. The second dummy layer 605 may include, for example, a material having an etch selectivity with respect to the mask pattern 602P.

The second dummy layer 605 may be formed, for example, by a chemical vapor deposition (CVD) or physical vapor deposition (PVD) process. For example, the second dummy layer 605 may be deposited on upper surfaces and sidewalls of the mask patterns 602P, and the upper surface of the substrate 10, and then its upper surface may be etched at least partially by an etch back or CMP process. For example, the second dummy layer 605 may be etched such that an upper surface of the second dummy layer 605 may become flat with the upper surface of the mask pattern 602P. Accordingly, the second dummy layer 605 may remain between the mask patterns 602P. Thereafter, a photoresist layer 606 may be formed on the second dummy layer 605 and the mask patterns 602P.

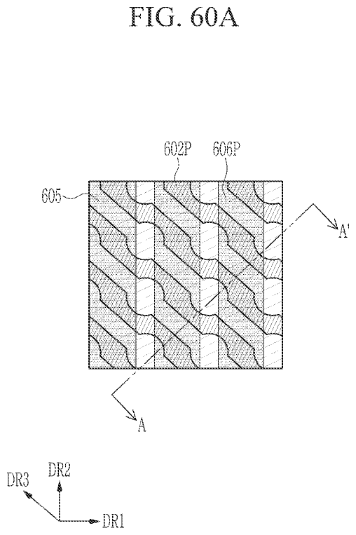

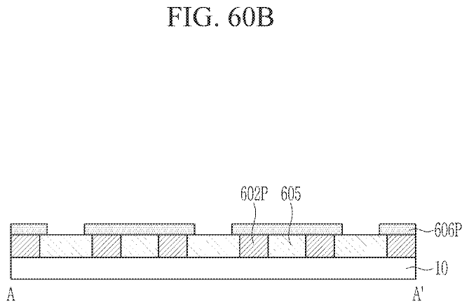

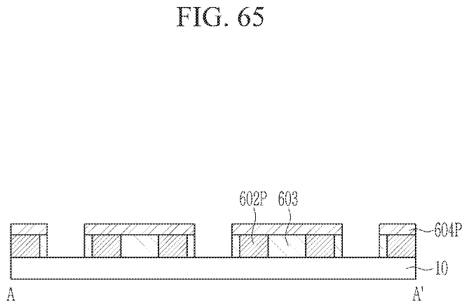

Referring to FIG. 60A and FIG. 60B, photoresist patterns 606P are formed by patterning the photoresist layer 606. FIG. 60B is a cross-sectional view taken along line A-A′ of FIG. 65A.

For example, the photoresist patterns 606P may be formed in line-shaped patterns extending in the second direction DR2. The line-shaped patterns may be disposed repeatedly and spaced apart along the first direction DR1.

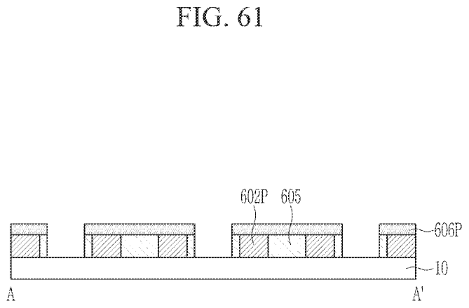

FIG. 61 shows a process after FIG. 60A and FIG. 60B, and shows a cross-section taken along the same direction as FIG. 60B. Referring to FIG. 61, the etching process may be performed by using the photoresist patterns 606P as a mask. The second dummy layer 605 and the mask patterns 602P that are not covered by the photoresist patterns 606P may be removed. The second dummy layer 605 and the mask patterns 602P that are covered by the photoresist patterns 606P may remain.

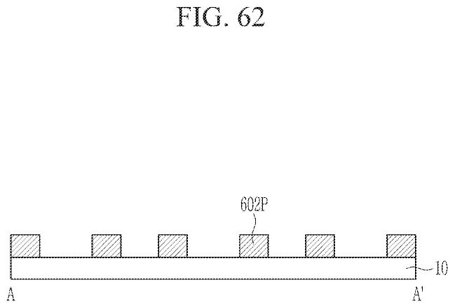

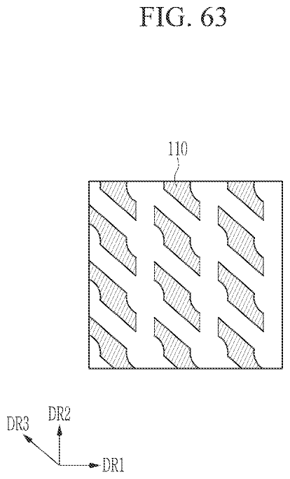

FIG. 62 shows a process after FIG. 61. Referring to FIG. 62, the photoresist patterns 606P and the remaining second dummy layer 605 may be removed. For example, the photoresist patterns 606P may be removed first, and then the second dummy layer 605 may be removed. As another example, the photoresist patterns 606P and the second dummy layer 605 may be removed all at once.

For example, the photoresist patterns 606P may be removed by a strip process or an ashing process, and the second dummy layer 605 may be removed by a dry or wet etching process. The second dummy layer 605 may include a material having an etch selectivity with respect to the mask pattern 602P. Accordingly, only the mask patterns 602P may remain. The remaining mask patterns 602P may correspond to the active patterns 110 of FIG. 63.

For example, after the processes shown in FIG. 51A to FIG. 62, a trench may be formed in the upper portion of the substrate 10 by using the remaining mask patterns 602P as an etch mask. By disposing a device isolation pattern within the trench, the active patterns 110 of FIG. 63 may be defined. The active pattern 110 of FIG. 63 may be the active pattern 110 of FIG. 5G.

The process of FIG. 64A and FIG. 64B may correspond to process of FIG. 56A and FIG. 56B. For example, after performing the process of FIG. 55, the process of FIG. 64A and FIG. 64B may be performed.

Referring to FIG. 64A and FIG. 64B, the hard mask pattern 604P is formed by patterning the hard mask layer 604. FIG. 64B is a cross-sectional view taken along line A-A′ of FIG. 64A. The hard mask pattern 604P may be formed through two or more processes. For example, by applying photoresist on the hard mask layer 604, and the photoresist pattern may be formed by processing a primary exposure and a secondary exposure and then developing. Subsequently, by using the photoresist pattern, the hard mask pattern 604P may be formed by etching the hard mask layer 604. The plan view of FIG. 64A illustrates that third portions M4 in which the hard mask layer 604 is removed by the primary exposure and fourth portions M5 in which the hard mask layer 604 is removed by the secondary exposure are distinguished, and for convenience, the hard mask pattern 604P is not illustrated in FIG. 64A. A mask used for the primary exposure and a mask used for the secondary exposure may be different or may be the same. For example, the secondary exposure process may be performed by shifting the mask used for the primary exposure.

The third portion M4 and the fourth portion M5 may be circular, in a plan view. The third portions M4 are spaced apart from each other along the third direction DR3 and the fourth direction DR4 perpendicular to the third direction DR3, and may have a repeating pattern. The fourth portions M5 are repeatedly arranged along the third direction DR3 and the fourth direction DR4 perpendicular to the third direction DR3, and may have a pattern disposed in a staggered manner with the third portions M4. The third portion M4 and the fourth portion M5 may be alternately disposed in the first direction DR1 and the second direction DR2.

For example, the third portion M4 and the fourth portion M5 may be smaller than the first portion M1 and the second portion M2 of FIG. 56A.

FIG. 65 shows a process after FIG. 64A and FIG. 64B, and shows a cross-section taken along the same direction as FIG. 64B. Referring to FIG. 65, the etching process is performed by using the hard mask pattern 604P as an etch mask. The first dummy layer 603 and the mask patterns 602P that are not covered by the hard mask pattern 604P may be removed. The first dummy layer 603 and the mask patterns 602P that are covered by the hard mask pattern 604P may remain.

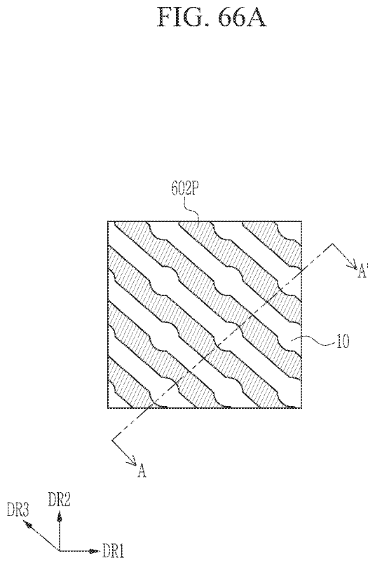

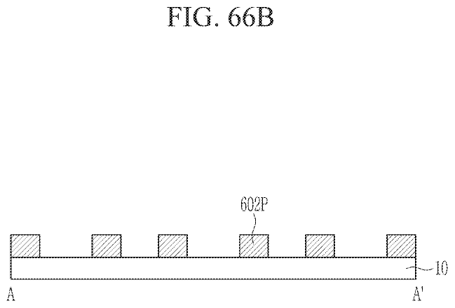

Referring to FIG. 66A and FIG. 66B, the hard mask pattern 604P and the remaining first dummy layer 603 are removed. FIG. 66B is a cross-sectional view taken along line A-A′ of FIG. 66A. For example, the hard mask pattern 604P may be removed first, and then the first dummy layer 603 may be removed. As another example, the hard mask pattern 604P and the first dummy layer 603 may be removed all at once.

For example, the hard mask pattern 604P and the first dummy layer 603 may be etched by a dry or wet etching process. The hard mask pattern 604P and the first dummy layer 603 may include a material having an etch selectivity with respect to the mask pattern 602P. Accordingly, only the mask patterns 602P may remain.

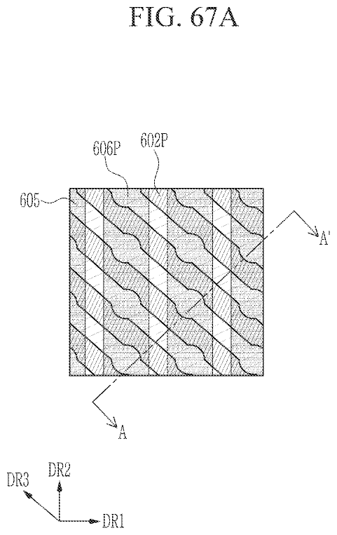

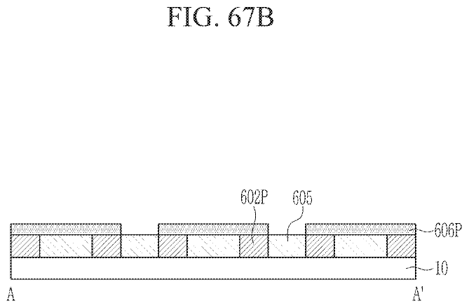

FIG. 67A and FIG. 67B show a process after FIG. 66A and FIG. 66B. Referring to FIG. 67A and FIG. 67B, the second dummy layer 605 may be formed. The second dummy layer 605 may include, for example, a material having an etch selectivity with respect to the mask pattern 602P.

The second dummy layer 605 may be formed, for example, by a chemical vapor deposition (CVD) or physical vapor deposition (PVD) process. For example, the second dummy layer 605 may be deposited on upper surfaces and sidewalls of first mask layer 602, and the upper surface of the substrate 10, and then its upper surface may be etched at least partially by an etch back or CMP process. For example, the second dummy layer 605 may be etched such that the upper surface of the second dummy layer 605 may become flat with the upper surface of the mask pattern 602P. Accordingly, the second dummy layer 605 may remain between the mask patterns 602P.

Thereafter, the photoresist layer 606 may be formed on the second dummy layer 605 and the mask patterns 602P. Subsequently, the photoresist patterns 606P may be formed by patterning the photoresist layer 606.

For example, the photoresist patterns 606P may be formed in line-shaped patterns extending in the second direction DR2. The line-shaped patterns may be disposed repeatedly and spaced apart along the first direction DR1. For example, in order to form the photoresist patterns 606P of FIG. 67A and FIG. 67B, the exposure process may be performed by shifting the photomask for forming the photoresist patterns 606P of FIG. 60A and FIG. 60B in the first direction DR1.

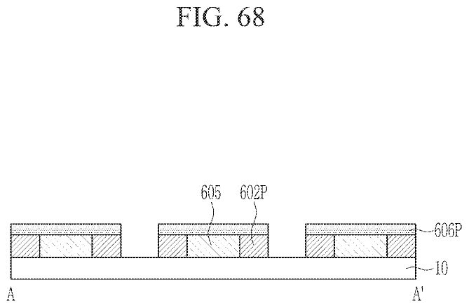

FIG. 68 shows a process after FIG. 67A and FIG. 67B, and shows a cross-section taken along the same direction as FIG. 67B. Referring to FIG. 68, the etching process is performed by using the photoresist patterns 606P as a mask. The second dummy layer 605 and the mask patterns 602P that are not covered by the photoresist patterns 606P may be removed. The second dummy layer 605 and the mask patterns 602P that are covered by the photoresist patterns 606P may remain.

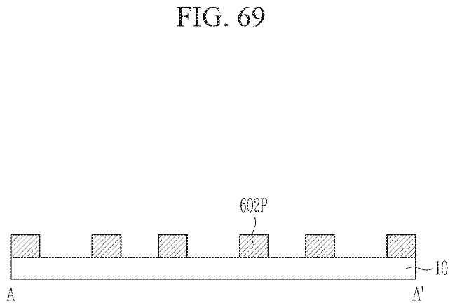

FIG. 69 shows a process after FIG. 68. Referring to FIG. 69, the photoresist patterns 606P and the remaining second dummy layer 605 may be removed. For example, the photoresist patterns 606P may be removed first, and then the second dummy layer 605 may be removed. As another example, the photoresist patterns 606P and the second dummy layer 605 may be removed all at once.

For example, the photoresist patterns 606P may be removed by a strip process or an ashing process, and the second dummy layer 605 may be removed by a dry or wet etching process. The second dummy layer 605 may include a material having an etch selectivity with respect to the mask pattern 602P. Accordingly, only the mask patterns 602P may remain. The remaining mask patterns 602P may correspond to the active patterns 110 of FIG. 70.

For example, after the processes shown in FIG. 51A to FIG. 55, and FIG. 64A to FIG. 69, a trench may be formed in the upper portion of the substrate 10 by using the remaining mask patterns 602P as an etch mask. By disposing a device isolation pattern within the trench, the active patterns 110 of FIG. 70 may be defined. The active pattern 110 of FIG. 70 may be the active pattern 110 of FIG. 5H.

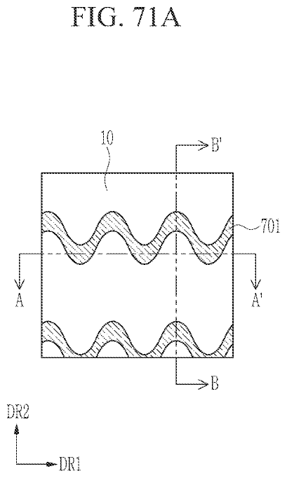

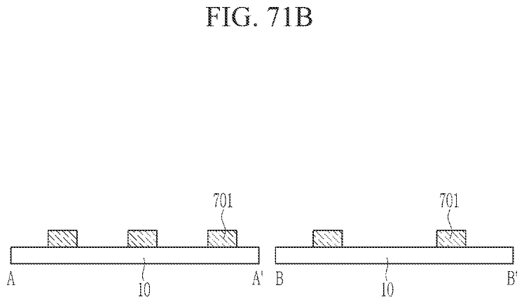

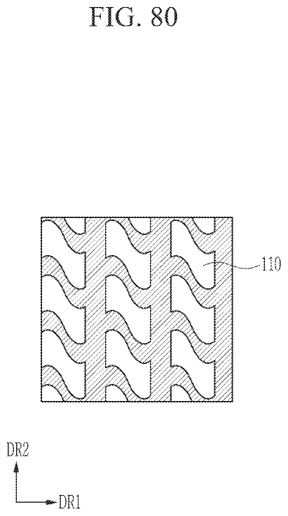

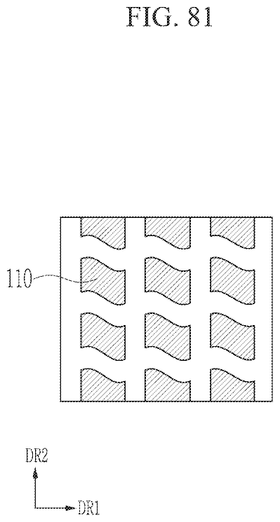

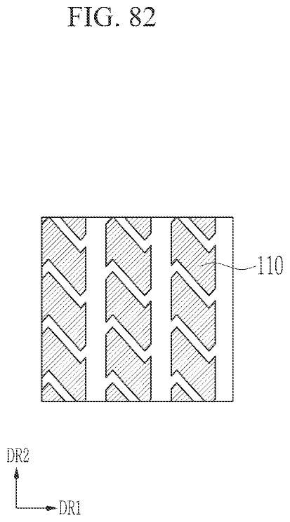

FIG. 71A to FIG. 82 are plan views and cross-sectional views showing an example of a process for patterning the active pattern 110. By the process shown in FIG. 71A to FIG. 79, FIG. 80, FIG. 81, or the active patterns 110 shown in FIG. 82 may be formed.

Referring to FIG. 71A and FIG. 71B, auxiliary mask patterns 701 are formed on the substrate 10. FIG. 71B shows a cross-section taken along line A-A′ of FIG. 71A and a cross-section taken along line B-B′ of FIG. 71A. The auxiliary mask pattern 701 extends along the first direction DR1 and may have a wavy shape that repeatedly goes up and down in the second direction DR2. The auxiliary mask patterns 701 may be spaced apart at a regular interval in the second direction DR2. The auxiliary mask patterns 701 may be formed, for example, by an extreme ultraviolet lithography (EUV) process using a light source with an extreme ultraviolet ray wavelength.

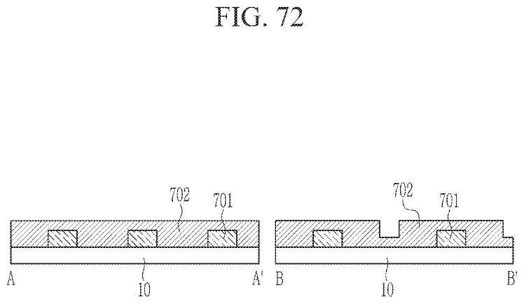

FIG. 72 shows a process after FIG. 71A and FIG. 71B. Referring to FIG. 72, a mask layer 702 is formed. The mask layer 702 may be formed, for example, by an atomic layer deposition (ALD) process. The mask layer 702 may have a conformal shape. The mask layer 702 may be disposed on an upper surface and a sidewall of the auxiliary mask patterns 701. The mask layer 702 may be disposed on the upper surface of the substrate 10 positioned between the auxiliary mask patterns 701.

The mask layer 702 may include, for example, a material having an etch selectivity with respect to the auxiliary mask pattern 701.

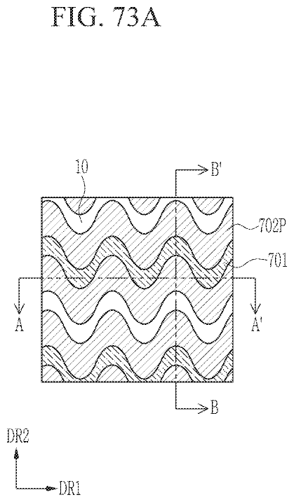

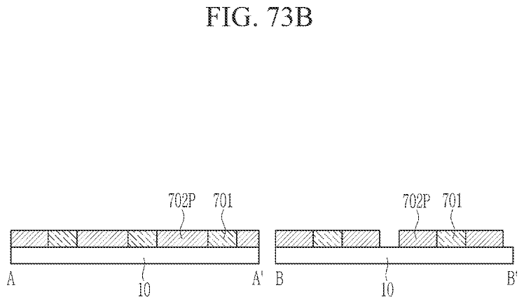

Subsequently, by etching at least a portion of the mask layer 702, as shown in FIG. 73A and FIG. 73B, mask patterns 702P may be formed. FIG. 73B shows a cross-section taken along line A-A′ of FIG. 73A and a cross-section taken along line B-B′ of FIG. 73A. For example, by using anisotropic etching process, the mask layer 702 positioned on the auxiliary mask patterns 701 and the upper surface of the substrate 10 may be removed. Accordingly, the mask layer 702 may remain only on both sides of the auxiliary mask patterns 701, and may be the mask pattern 702P. For example, an upper surface of the mask pattern 702P may be positioned at the same level with upper surfaces of the auxiliary mask pattern 701. A thickness of the mask pattern 702P in the vertical direction may correspond to a thickness of the auxiliary mask pattern 701 in the vertical direction.

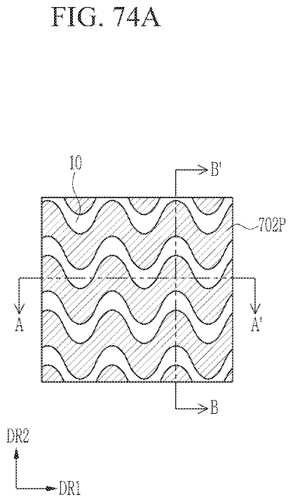

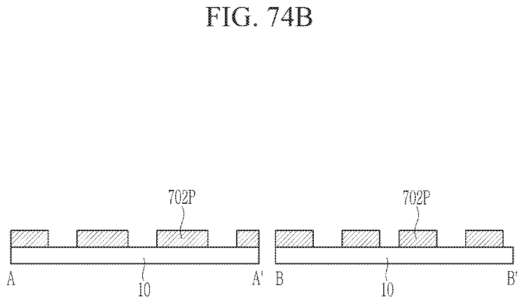

Referring to FIG. 74A and FIG. 74B, the auxiliary mask patterns 701 is removed, and only the mask patterns 702P remains. FIG. 74B shows a cross-section taken along line A-A′ of FIG. 74A and a cross-section taken along line B-B′ of FIG. 74A. The auxiliary mask patterns 701 may be etched, for example, by a dry or wet etching process.

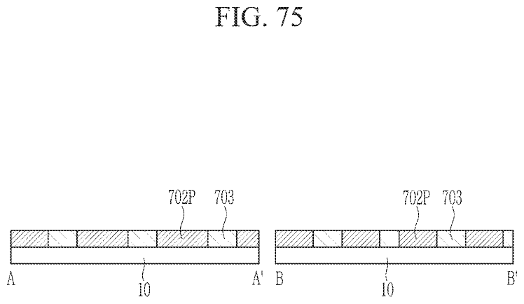

FIG. 75 shows a process after FIG. 74A and FIG. 74B. Referring to FIG. 75, a dummy layer 703 may be formed. The dummy layer 703 may include, for example, a material having an etch selectivity with respect to the mask pattern 702P.

The dummy layer 703 may be formed, for example, by a chemical vapor deposition (CVD) or physical vapor deposition (PVD) process. For example, the dummy layer 703 may be deposited on the substrate 10 to fill a space between the mask patterns 702P, and then its upper surface may be etched at least partially by an etch back or CMP process. For example, the first dummy layer 703 may be etched such that an upper surface of a first dummy layer 703 may become flat with the upper surface of the mask pattern 702P. Accordingly, the dummy layer 703 may remain between the mask patterns 702P.

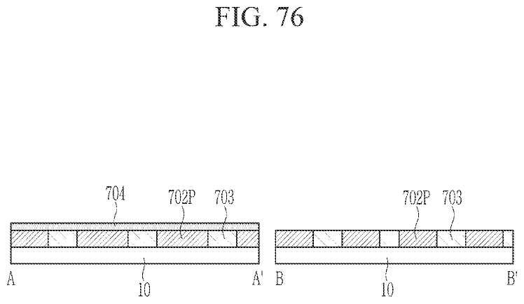

FIG. 76 shows a process after FIG. 75. Referring to FIG. 76, a photoresist layer 704 may be formed on the dummy layer 703 and the mask patterns 702P.

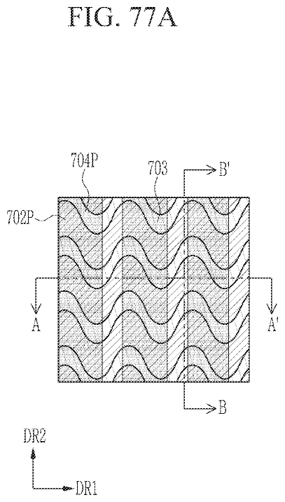

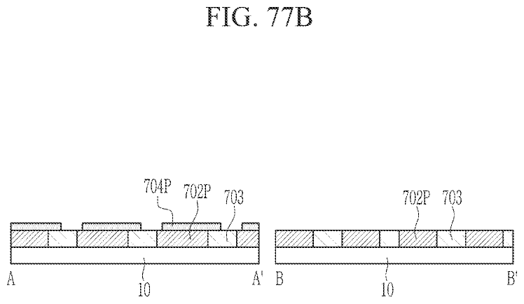

Referring to FIG. 77A and FIG. 77B, photoresist patterns 704P may be formed by patterning the photoresist layer 704. FIG. 77B shows a cross-section taken along line A-A′ of FIG. 77A and a cross-section taken along line B-B′ of FIG. 77A.

For example, the photoresist patterns 704P may be formed in line-shaped patterns extending in the second direction DR2. The line-shaped patterns may be disposed repeatedly and spaced apart along the first direction DR1.

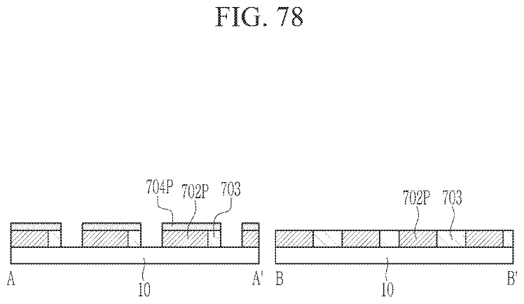

FIG. 78 shows a process after FIG. 77A and FIG. 77B, and shows a cross-section taken along the same direction as FIG. 77B. Referring to FIG. 78, the etching process is performed by using the photoresist patterns 704P as a mask. The dummy layer 703 and the mask patterns 702P that are not covered by the photoresist patterns 704P may be removed. The dummy layer 703 and the mask patterns 702P that are covered by the photoresist patterns 704P may remain.

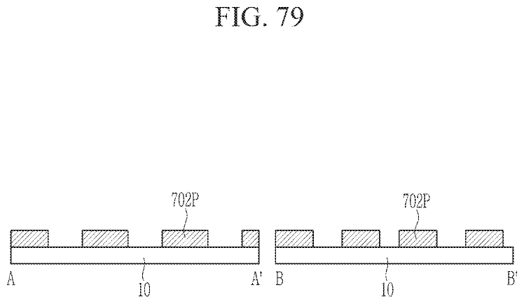

FIG. 79 shows a process after FIG. 78. Referring to FIG. 79, the photoresist patterns 704P and the remaining dummy layer 703 are removed. For example, the photoresist patterns 704P may be removed first, and then the dummy layer 703 may be removed. As another example, the photoresist patterns 704P and the dummy layer 703 may be removed all at once.

For example, the photoresist patterns 704P may be removed by a strip process or an ashing process, and the dummy layer 703 may be removed by a dry or wet etching process. The dummy layer 703 may include a material having an etch selectivity with respect to the mask pattern 702P. Accordingly, only the mask patterns 702P may remain. The remaining mask patterns 702P may correspond to the active patterns 110 of FIG. 80.

For example, after the processes shown in FIG. 71A to FIG. 79, a trench may be formed in the upper portion of the substrate 10 by using the remaining mask patterns 702P as an etch mask. By disposing a device isolation pattern within the trench, the active patterns 110 of FIG. 80 may be defined. The active pattern 110 of FIG. 80 may be the active pattern 110 of FIG. 5I.

If the shape of the auxiliary mask pattern 701 formed in FIG. 71A and FIG. 71B is modified, by the process shown in FIG. 71A to FIG. 79, the active patterns 110 shown in FIG. 81 or FIG. 82 may be formed. For example, when the height difference in the second direction DR2 of the auxiliary mask pattern 701 is lowered, the active patterns 110 shown in FIG. 81 may be formed. As another example, when the auxiliary mask pattern 701 is formed to have a zigzag shape when viewed in the first direction DR1, the active patterns 110 shown in FIG. 82 may be formed.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the embodiment of the present disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor device, comprising:
a plurality of active patterns disposed on a substrate;
a gate structure extending in a first direction parallel to an upper surface of the substrate;
a bit line structure extending in a second direction parallel to the upper surface of the substrate and crossing the first direction; and
a plurality of capacitors electrically connected to the plurality of active patterns, respectively,
wherein the plurality of active patterns have a shape extending in a third direction oblique to the first direction and the second direction,
wherein the gate structure passes through centers of the plurality of active patterns,
wherein the bit line structure is connected to first end portions of the plurality of active patterns,
wherein the plurality of capacitors are connected to second end portions of the plurality of active patterns, respectively,
wherein the first end portion and the second end portion are positioned at opposite sides with respect to the gate structure, and
wherein the first end portion and the second end portion have point-symmetrical shapes with respect to a center of the active pattern.

2. The semiconductor device of claim 1, wherein widths along the second direction of the first end portion and the second end portion of the active pattern are greater than a width along the second direction of an intermediate portion between the first end portion and the second end portion.

3. The semiconductor device of claim 2, wherein, in a plan view of the substrate, at least one side surface of the first end portion, the second end portion, and a side surface of the intermediate portion extends along the third direction in a straight line.

4. The semiconductor device of claim 2, wherein, in a plan view of the substrate, a side surface of the first end portion, the second end portion, and the intermediate portion surface extends along the third direction in a continuous curved line.

5. The semiconductor device of claim 1, wherein the active pattern includes at least one bent portion that is oblique to the first direction and the second direction and bends from the third direction to a fourth direction different from the third direction.

6. The semiconductor device of claim 5, wherein the bent portion is positioned in a central portion of the active pattern.

7. The semiconductor device of claim 5, wherein the bent portion is positioned between a central portion of the active pattern and the first end portion or the second end portion.

8. The semiconductor device of claim 1, wherein, in a plan view, both side surfaces of the active pattern facing each other include a respective recess.

9. The semiconductor device of claim 8, wherein each recess of the respective recesses is positioned on a side surface extending along the third direction.

10. The semiconductor device of claim 8, wherein each recess of the respective recesses is positioned on a first side surface extending along the third direction and a second side surface extending from the first side surface and extending along the second direction.

11. The semiconductor device of claim 1, wherein the active pattern has a wavy shape having a uniform width in the second direction, in a plan view.

12. The semiconductor device of claim 1, further comprising:
first contact plugs contacting upper surfaces of the second end portions of the plurality of active patterns, respectively; and
contact structures contacting at least partially upper surfaces of the first contact plugs, respectively,
wherein the capacitor contacts the contact structure.

13. The semiconductor device of claim 12, wherein the contact structures are arranged in a honeycomb pattern disposed each vertex of a hexagon and center of the hexagon, in a plan view.

14. The semiconductor device of claim 1, wherein the third direction is inclined from the first direction at an angle of 35 degrees or more and 50 degrees or less.

15. A semiconductor device, comprising:
a plurality of active patterns disposed on a substrate;
a gate structure extending in a first direction parallel to an upper surface of the substrate;
a bit line structure extending in a second direction parallel to the upper surface of the substrate and crossing the first direction; and
a plurality of capacitors electrically connected to the plurality of active patterns, respectively,
wherein the plurality of active patterns have a shape extending in a third direction oblique to the first direction and the second direction,
wherein the gate structure passes through centers of the plurality of active patterns,
wherein the bit line structure is connected to first end portions of the plurality of active patterns,
wherein the plurality of capacitors are connected to second end portions of the plurality of active patterns, respectively,
wherein the first end portion and the second end portion are positioned at opposite sides with respect to the gate structure, and
wherein a width along the second direction of the first end portion and the second end portion is greater than a width along the second direction of an intermediate portion between the first end portion and the second end portion.

16. The semiconductor device of claim 15, wherein the active pattern a point-symmetrical shape with respect to a center of the active pattern.

17. The semiconductor device of claim 15, wherein a side surface extending along the third direction connecting the first end portion or the second end portion and the intermediate portion is a curved surface.

18. The semiconductor device of claim 15, wherein a side surface extending along the third direction connecting the first end portion or the second end portion and the intermediate portion has a stepped shape.

19. The semiconductor device of claim 15, wherein a planar shape of the first end portion or the second end portion is a circular sector.

20. A semiconductor device, comprising:
a plurality of active patterns disposed on a substrate;
a gate structure extending in a first direction parallel to an upper surface of the substrate;
a bit line structure extending in a second direction parallel to the upper surface of the substrate and crossing the first direction; and
a plurality of capacitors electrically connected to the plurality of active patterns, respectively,
wherein the plurality of active patterns have a shape extending in a third direction oblique to the first direction and the second direction,
wherein each active pattern comprises, in a plan view;
a central portion through which the gate structure passes;
a first end portion connected to the bit line structure; and
a second end portion connected to the capacitor,
wherein the first end portion and the second end portion are positioned at opposite sides of the gate structure,
wherein the first end portion and the second end portion have a point-symmetrical shape with respect to a center of each active pattern, and
wherein central portions of the plurality of active patterns are arranged along the first direction, first end portions of the plurality of active patterns are arranged along the second direction, and second end portions of the plurality of active patterns are arranged along in the second direction.
